(19) United States
(12) Patent Application Publication
(10) Pub. No.: US 2011/0006353 A1
(43) Pub. Date: Jan. 13, 2011

(54) DRAM DEVICES

(76) Inventors: Min-Sang KIM, Seoul (KR); Dong-Won Kim, Seongnam-si (KR); Jun Seo, Asan-si (KR); Keun-Hwi Cho, Seoul (KR); Hyun-Jun Bae, Suwon-si (KR); Ji-Myoung Lee, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/830,788

(22) Filed: Jul. 6, 2010

(30) Foreign Application Priority Data
Jul. 9, 2009 (KR) 10-2009-0062413

(51) Int. Cl. H01L 27/108

(52) U.S. Cl. 257/300; 257/296; 257/E27.084

(57) ABSTRACT

A DRAM device includes a plug on a substrate, a conductive plate electrically connected to the plug and overlapping the substrate, at least one capacitor on the substrate and spaced apart from the plug, and at least one word line under the conductive plate and spaced apart from the conductive plate. The DRAM device further includes at least one first conductive pad under the conductive plate, the at least one first conductive pad being spaced apart from the conductive plate in a first state and being electrically connected to the conductive plate in a second state, the at least one first conductive pad being disposed between the plug and an adjacent word line of the at least one word line, and the at least one first conductive pad being electrically connected to a respective capacitor of the at least one capacitor.

### BACKGROUND

1. Field

Embodiments relate to dynamic random access memory (DRAM) devices and methods of manufacturing the same. More particularly, example embodiments relate to DRAM devices including an electromechanical switch and methods of manufacturing the same.

2. Description of the Related Art

DRAM devices may have a unit cell including a metal-oxide-semiconductor

(MOS) transistor and a capacitor, and data may be stored in the cell by storing charges in the capacitor.

Generally, the MOS transistor is formed on a single crystalline semiconductor substrate and the DRAM devices may not have a multi-stacked structure, which may limit the integration degree of the DRAM device. Additionally, the data stored in the capacitor may leak through a PN junction at source/drain regions of the MOS transistor, and refreshing operations are needed to compensate charges to the capacitor. As a result, DRAM devices having good data retention characteristics and high integration degree are needed.

### SUMMARY

Embodiments are therefore directed to DRAM devices and methods of manufacturing DRAM devices, which substantially overcome one or more of the problems due to the limitations and disadvantages of the related art.

It is therefore a feature of an embodiment to provide a DRAM device and methods of manufacturing the DRAM device that include a plug, a conductive plate, at least one capacitor, at least one word line, and at least one conductive pad.

Embodiments provide DRAM devices and methods of manufacturing DRAM devices having good data retention characteristics and low operation voltage.

At least one of the above and other features and advantages may be realized by providing a plug on a substrate, a conductive plate electrically connected to the plug and overlapping the substrate, at least one capacitor on the substrate and spaced apart from the plug, and at least one word line under the conductive plate and spaced apart from the conductive plate. The DRAM device may include at least one first conductive pad under the conductive plate, the at least one first conductive pad being spaced apart from the conductive plate in a first state and being electrically connected to the conductive plate in a second state, the at least one first conductive pad being disposed between the plug and an adjacent word line of the at least one word line, and the at least one first conductive pad being electrically connected to a respective capacitor of the at least one capacitor.

The DRAM device may further include a bitline electrically connected to the plug. The bitline may extend in a first direction and the at least one word line extends in a second direction of the substrate perpendicular to the first direction.

The conductive plate may include an anchor and a blade. The anchor may be electrically connected to the plug, and the blade may overlap a first conductive pad, a second conductive pad, a first word line, and a second word line. The first word line, the first conductive pad, the plug, the second conductive pad, and the second word line may be sequentially arranged on the substrate in a first direction of the substrate. In the first state a first distance between the conductive plate and the at least one conductive pad may be smaller than a second distance between the conductive plate and the at least one word line.

The DRAM device may further include a second conductive pad on the plug. The second conductive pad may be disposed on a same plane as the at least one word line is disposed.

The at least one capacitor may have a stacked structure including a first electrode, a dielectric layer pattern, and a second electrode. The first electrode and the at least one word line may extend in a second direction. The second electrode may have an island shape, may contact the conductive pad, and may be electrically connected to the conductive plate in the second state. The at least one capacitor may have a cylindrical shape including a cylindrical first electrode, a cylindrical dielectric layer pattern, and a second electrode. The second electrode may fill a space formed by the cylindrical dielectric layer pattern.

The plug, the conductive plate, the at least one capacitor, the at least one word line, and the at least one first conductive pad may define a first memory cell of the DRAM device. The DRAM device may further include an insulation layer on the first memory cell, the insulation layer having a space around the conductive plate. The DRAM device may also include at least one stacked memory cell on the insulation layer.

The substrate may have a cell region and a peripheral region. The plug, the conductive plate, the at least one capacitor, the at least one word line, and the first conductive pad may define a memory cell in the cell region. The peripheral region may include a metal-oxide-semiconductor (MOS) transistor and wirings. The MOS transistor and the wirings may be configured to apply an electrical signal to the memory cell.

At least one of the above and other features and advantages may also be realized by providing a method of manufacturing a DRAM device that may include forming a plug on the substrate, forming at least one capacitor on the substrate spaced apart from the plug, and forming at least one word line over the capacitor and spaced apart from the plug. The method may include forming at least one first conductive pad between the plug and an adjacent word line of the at least one word line. The at least one first conductive pad may be electrically connected to a respective capacitor of the at least one capacitor. The method may further include foaming a conductive plate overlapping the at least one first conductive pad and the at least one word line, the conductive plate being electrically connected to the plug and spaced apart from the at least one first conductive pad.

Forming the at least one capacitor may include sequentially formed a first electrode layer, a dielectric layer, and a second electrode layer on the substrate. The second electrode layer, the dielectric layer, and the first electrode layer may be patterned to form an intermediate second electrode, an intermediate dielectric layer pattern, and a first electrode, respectively. The intermediate second electrode, the intermediate dielectric layer pattern, and the first electrode may extend in a second direction. The intermediate second electrode and the intermediate dielectric layer pattern may be patterned to form a plurality of second electrodes and a plurality of dielectric layer patterns, respectively. The second electrodes and the dielectric layer patterns may have an island shape.

The method may include forming at least two adjacent capacitors on the substrate, and the plug may be formed between the two adjacent capacitors. The method may further include forming a second conductive pad on the plug, and forming an insulating interlayer to fill spaces between the second conductive pad, the at least one first conductive pad, and the at least one word line. The insulating interlayer may have a top surface coplanar with top surfaces of the second conductive pad, the at least one first conductive pad, and the at least one word line.

Forming the conductive plate may include forming a sacrificial layer on the insulating interlayer to have a first thickness at a first portion overlapping the word line and a second thickness at a second portion overlapping the first conductive pad. The first thickness may be greater than the second thickness. The sacrificial layer may be partially removed to form a first opening exposing the plug. A conductive layer may be formed on an inner wall of the first opening and on the sacrificial layer. The conductive layer may be patterned to form the conductive plate. The sacrificial layer under the conductive plate may be removed patterning the conductive layer to form the conductive plate.

The method may further include forming a bitline on the substrate, and forming an insulating interlayer on the substrate to cover the bitline.

The substrate may have a cell region and a peripheral region. The plug, the conductive plate, the at least one capacitor, the at least one word line, and the at least one first conductive pad may define a memory cell in the cell region. The peripheral region may include a MOS transistor and wirings. The MOS transistor and the wirings may be configured to apply an electrical signal to the memory cell in the cell region. The MOS transistor may further include a gate electrode, and cell region may include a bitline on the substrate. The bitline and the gate electrode may be simultaneously formed.

The DRAM device may have low operation voltage and high data retention. Additionally, the DRAM device may have a stacked structure and have a high integration degree. Furthermore, the DRAM device may be foamed on a substrate including an insulating material.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a cross-sectional view of a DRAM device in accordance with an exemplary embodiment;

FIG. 2 illustrates a perspective view of the DRAM device of FIG. 1;

FIG. 3 illustrates a perspective view of a portion of the DRAM device of FIG. 1;

FIGS. 4 to 15 illustrate cross-sectional views of a method of manufacturing the DRAM device of FIG. 1 in accordance with an exemplary embodiment;

FIGS. 16 to 20 illustrate top views of a method of manufacturing the DRAM device of FIG. 1;

FIGS. 21 and 22 illustrate cross-sectional views of a method of manufacturing the DRAM device of FIG. 1 in accordance with an exemplary embodiment;

FIGS. 23 to 25 illustrate cross-sectional views of a method of manufacturing the DRAM device of FIG. 1 in accordance with an exemplary embodiment;

FIG. 26 illustrates a cross-sectional view of a DRAM device in accordance with an exemplary embodiment;

FIGS. 27 to 29 illustrate cross-sectional views of a method of manufacturing the DRAM device of FIG. 26 in accordance with an exemplary embodiment;

FIG. 30 illustrates a cross-sectional view of a DRAM device in accordance with an exemplary embodiment;

FIG. 31 illustrates a cross-sectional view of a DRAM device in accordance with an exemplary embodiment;

FIG. 32 illustrates a cross-sectional view of a DRAM device in accordance with an exemplary embodiment;

FIGS. 33 to 35 illustrate cross-sectional views of a method of manufacturing the DRAM device of FIG. 32 in accordance an exemplary embodiment;

FIG. 36 illustrates a cross-sectional view of a stacked DRAM device in accordance with an exemplary embodiment;

FIGS. 37 and 38 illustrate cross-sectional views of a method of manufacturing the stacked DRAM device of FIG. 36 in accordance with an exemplary embodiment;

FIG. 39 illustrates a cross-sectional view of a DRAM device in accordance with an exemplary embodiment;

FIG. 40 illustrates a perspective view of a switching device of a comparative example;

FIG. 41 illustrates a graph showing the movement of a conductive plate versus the applied voltage to a word line in accordance with an exemplary embodiment; and

FIG. 42 illustrates a graph showing the movement of a conductive plate versus the applied voltage to a word line in accordance with an exemplary embodiment.

### DETAILED DESCRIPTION

Korean Patent Application No. 10-2009-0062413, filed on Jul. 9, 2009, in the Korean Intellectual Property Office, and entitled: “Dram Devices and Methods of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

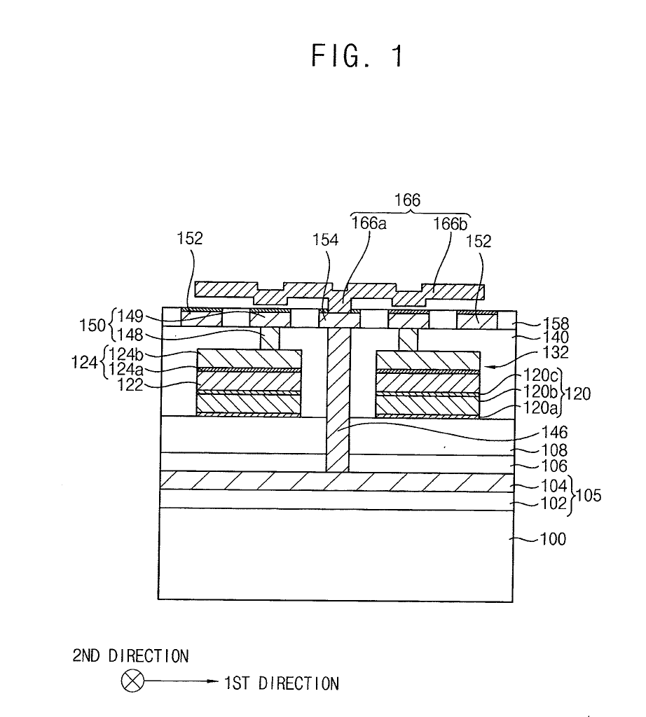

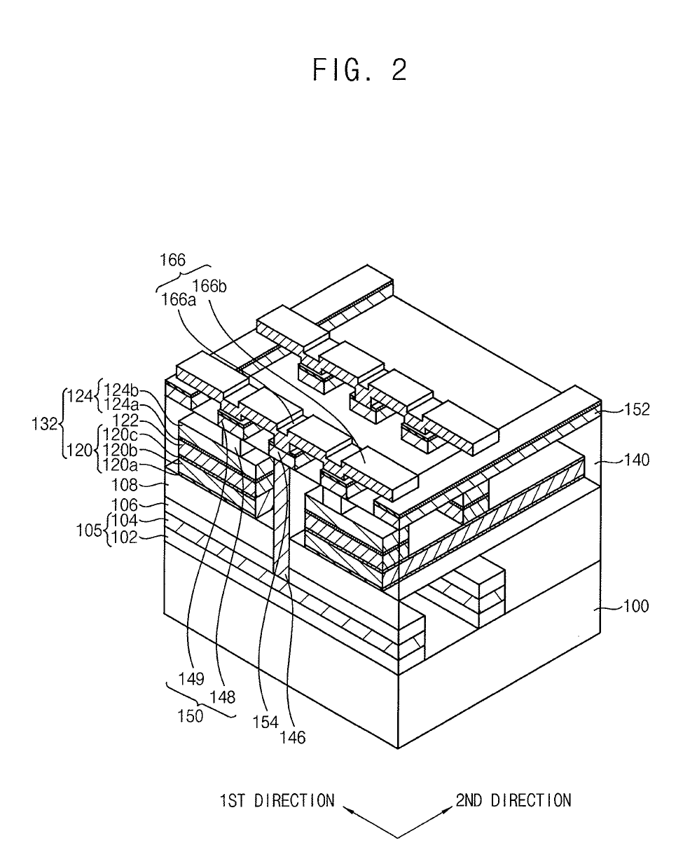

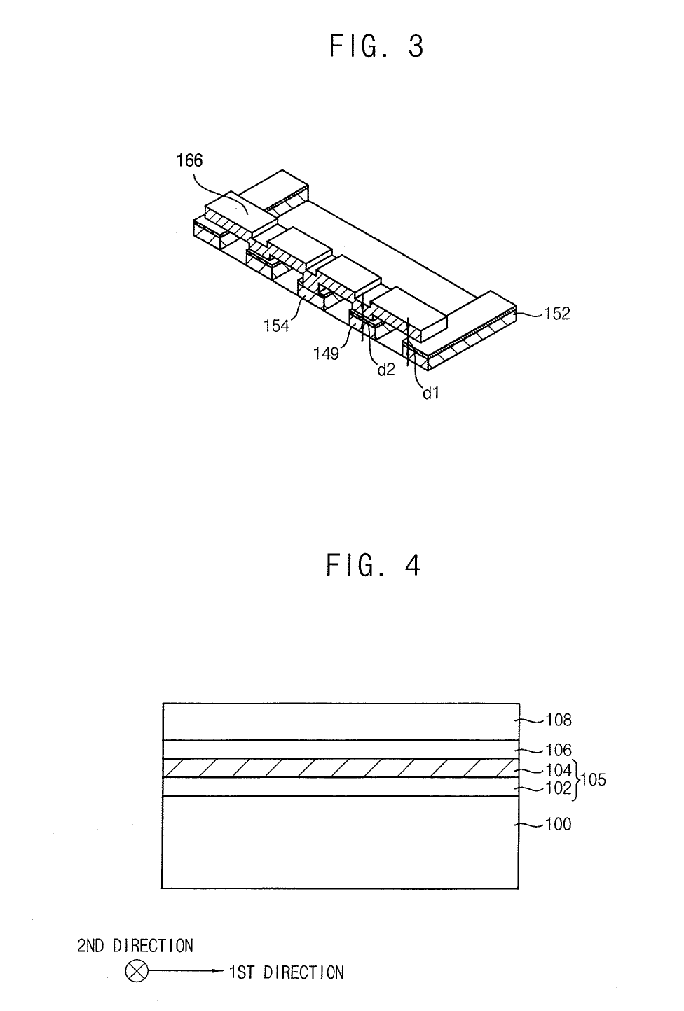

FIG. 1 illustrates a cross-sectional view of an exemplary DRAM device, FIG. 2 illustrates a perspective view of the DRAM device of FIG. 1, and FIG. 3 illustrates a perspective view of a portion of the DRAM device of FIG. 1.

Referring to FIGS. 1 to 3, the DRAM device may include a plurality of bitline structures extending in a first direction of a substrate 100, e.g., the bitlines structures may be elongated in the first direction. The bitline structures may be arranged in a second direction of the substrate 100, and the second direction may be perpendicular to the first direction. For example, the bitline structures may be arranged parallel to adjacent bitline structures in the second direction. The substrate 100 may not include a semiconductor material because a cell array of the DRAM device may not include a MOS transistor. The substrate 100 may include any material, e.g. plastic, and may have an insulating material thereon.

The bitline structure may have a stacked structure including a bitline 105 and a first hard mask 106 formed on the bitline 105. The bitline 105 may include a metal having a low resistance. In an exemplary embodiment, the bitline 105 may have a stacked structure including a silicon layer 102 and a metal layer 104, e.g., a polysilicon layer pattern 102 and a tungsten silicide layer pattern 104. The DRAM device may include a first insulating interlayer 108 covering the bitline structures.

The DRAM device may include a plurality of capacitors 132 formed on the first insulating interlayer 108. The capacitor 132 may have a stacked structure, e.g., a stack-type capacitor, including a first electrode 120, a dielectric layer 122, and a second electrode 124.

According to an exemplary embodiment of the capacitors 132, the first electrodes 120 may be formed in the first direction on the first insulating interlayer 108. For example, the first electrodes 120 may extend in the second direction, e.g., the first electrodes 120 may be elongated in the second direction. The first electrodes 120 may be arranged in the first direction, e.g., arranged parallel to adjacent first electrodes 120 of adjacent capacitors 132 in the first direction. The dielectric layers 122 and the second electrodes 124 may have an island shape on the first electrodes 120, e.g., a plurality of individual spaced apart dielectric layers 122 and a plurality of individual spaced apart second electrodes 124 may be formed on the first electrodes 120. The island-shaped dielectric layers 122 and second electrodes 124 may substantially completely overlap each other, e.g., the island-shaped dielectric layers 122 may have the same shape as the corresponding island-shaped second electrodes 124. The island-shaped second electrodes 124 may overlap a portion of the island-shaped dielectric layers 122, e.g., two island-shaped second electrodes 124 may be arranged on one island-shaped dielectric layer 122. The first electrodes 120 may serve as a common plate electrode of the capacitors 132 that are arranged in the second direction, e.g., one first electrode 120 may be a common electrode for a plurality of capacitors 132 that are arranged parallel to each other in the second direction. The dielectric layers 122 and the second electrodes 124 may overlap the bitline structure.

The first electrodes 120 may include a metal, e.g., the first electrodes 120 may have a stacked structure including a first barrier metal layer 120a, a metal layer 120b, and a second barrier metal layer 120c. In an exemplary embodiment, the first electrodes 120 may have a stacked structure including a titanium nitride layer pattern, a tungsten layer pattern, and a titanium nitride layer pattern.

The dielectric layers 122 may include a material having a high dielectric constant, i.e., a high-k material. The dielectric layers 122 may include at least one of, e.g., aluminum oxide, zirconium oxide, hafnium oxide, tantalum oxide, and a combination thereof. In an exemplary embodiment, the dielectric layers 122 may have a stacked structure including zirconium oxide, aluminum oxide, and zirconium oxide.

The second electrodes 124 may include a metal, e.g., the second electrodes 124 may have a stacked structure including a barrier metal layer 124a and a metal layer 124b. In an exemplary embodiment, the second electrode 124 may have a stacked structure including a titanium nitride layer pattern and a tungsten layer pattern.

A second insulating interlayer 140 covering the capacitors 132 may be formed on the first insulating interlayer 108. The second insulating layer 140 may insulate the capacitors 132 from adjacent capacitors 132.

A first plug 146 may be formed through the first and second insulating interlayers 108 and 140 and the first hard mask 106 of the bitline structure. The first plug 146 may be electrically connected to the bitline 105, and the first plug 146 may be directly coupled to the bitline 105. In an exemplary embodiment, the first plug 146 may be formed between two adjacent capacitors 132, and may be electrically insulated from the two adjacent capacitors 132, e.g., by the second insulating layer 140. The first plug 146 may include a metal, e.g. tungsten. The first plug 146 may include a barrier layer (not shown) formed thereon, e.g., along lateral sides of the first plug 146.

A plurality of lower conductive pads 148 may be formed extending through a portion of the second insulating interlayer 140, e.g., the lower conductive pads 148 may extend through the portion of second insulating interlayer 140 above a corresponding capacitor 132. The lower conductive pads 148 may be electrically connected to corresponding second electrodes 124 of the capacitors 132, and the lower conductive pads 148 may be directly coupled to the corresponding second electrodes 124, e.g., the metal layers 124b of the second electrodes 124. The lower conductive pads 148 may have top surfaces that are substantially coplanar with a top surface of the second insulating interlayer 140.

A plurality of upper conductive pads 149 may be formed on the lower conductive pads 148 and the second insulating interlayer 140. The lower and upper conductive pads 148 and 149 may form first conductive pads 150. The first conductive pads 150 may have an island shape. The upper conductive pads 149 may be electrically connected to corresponding lower conductive pads 148, and the upper conductive pads 149 may be directly coupled to the corresponding lower conductive pads 148. The upper conductive pads 149 may overlap substantially an entire length of the corresponding lower conductive pads 148 and a partial portion of the second insulating interlayer 140.

At least one second conductive pad 154 may be formed on the first plug 146. The second conductive pad 154 may be directly coupled to the plug 146. The second conductive pad 154 may overlap substantially an entire length of the plug 146 and a partial portion of the second insulating interlayer 140. The second conductive pad 154 may have an island shape, and the island shape may be substantially similar to the island shape of upper conductive pads 149 of the first conductive pads 150.

A plurality of word lines 152 may be formed on the second insulating interlayer 140. The word lines 152 may be formed extending in the second direction of the substrate 100, e.g., the word lines 152 may be elongated in the second direction. The word lines 152 may extend in a direction that is perpendicular to the direction that the bit lines 105 extend, e.g., the word lines 152 may extend in the second direction and the bit lines 105 may extend in the first direction of the substrate 100. The word lines 152 may be arranged in the first direction, e.g., arranged parallel to adjacent word lines 152 in the first direction. The word lines 152 may be spaced apart from the first conductive pads 150. The word lines 152 may be more distant, i.e., spaced further away, from the first plug 146 than the first conductive pads 150. The first conductive pads 150 may be disposed between the first plug 146 and an adjacent word line of the plurality of word lines 152.

The word lines 152 and the first and second conductive pads 150 and 154 may have top surfaces substantially coplanar with each other. The word lines 152 may be spaced apart from an adjacent upper conductive pad 149 of the first conductive pad 150 by a third insulating layer 158, and the upper conductive pad 149 may be spaced apart from an adjacent second conductive pad 154 by the third insulating layer 158. The third insulating layer 158 may fill spaces between the first conductive pads 150, the second conductive pads 154, and the word lines 152. A top surface of the third insulating layer 158 may be substantially coplanar with top surfaces of the word lines 152, the first conductive pads 150, and the second conductive pads 154.

The word lines 152, the upper conductive pads 149, and the second conductive pads 154 may include a metal and/or a metal layer. In exemplary embodiment, at least one of the word lines 152, the upper conductive pads 149, the second conductive pads 154, and combinations thereof may have a stacked structure including at least one tungsten layer and at least one titanium nitride layer.

As shown in FIGS. 1 to 3, the capacitors 132 may be formed under the word lines 152, such that a portion of the capacitors 132 overlaps a portion of corresponding word lines 152. The capacitors 132 may be arranged in the first direction, e.g., parallel to adjacent capacitors in the first direction. The capacitors 132 may contact, e.g., be directly coupled to, the lower conductive pads 148 of the first conductive pad 150. The capacitors 132 may have an enlarged area to, e.g., increase the capacitance.

First conductive plates 166 electrically connected to corresponding second conductive pads 154, may be formed extending in the first direction over the substrate 100, e.g., the first conductive plates 166 may be elongated in the first direction of the substrate 100. In a first state of the DRAM device, the first conductive plates 166 may be spaced apart from the corresponding word lines 152 and the corresponding first conductive pads 150. In a second state of the DRAM device, when an electric potential difference occurs between the first conductive plates 166 and the corresponding word lines 152, the first conductive plates 166 may move downward contacting the corresponding first conductive pads 150. In the second state, the first conductive plates 166 may be spaced apart from the corresponding word lines 152. In the second state, the first conductive plates 166 may be electrically connected to the corresponding capacitors 132, e.g., through the first conductive pads 150.

In an exemplary embodiment, e.g., as shown in FIG. 3, a first distance d1 between the first conductive plates 166 and the word lines 152 may be larger than a second distance d2 between the first conductive plates 166 and the upper conductive pads 149 of the first conductive pads 150. When an electrical signal is applied to the word lines 152, which may generate the electrical potential difference between the word lines 132 and the first conductive plates 166, the first conductive plates 166 may contact, e.g., directly contact, the corresponding first conductive pads 150. As a result, a pull-in voltage between the first conductive plates 166 and the word lines 152 may be reduced. When the conductive plates 166 contact the first conductive pads 150 in the second state, the first conductive plates 166 may be sufficiently spaced apart from the word lines 152 and a short circuit between the first conductive plates 166 and the word lines 152 may be prevented.

The first conductive plates 166 may include anchors 166a and blades 166b. The anchors 166a may contact, e.g., directly contact, the second conductive pad 154. The blades 166b may extend in the first direction, and may overlap the first conductive pads 150 and the word lines 152. In an exemplary embodiment, the blades 166b may have an unevenness shape, e.g., have jagged lateral sides foamed by a plurality of protrusions and recesses. The blades 166b may have a first distance d1 to the corresponding conductive pads 150 that is larger than a second direction d2 to the corresponding word lines 152.

The first conductive plates 166 may include a conductive material. The first conductive plates 166 may include a material having an elastic force and a restoring force. The first conductive plates 166 may have a single layer or a stacked layer structure. The first conductive plates 166 may include, e.g., at least one of titanium nitride, carbon nanotube (CNT), titanium, etc. In an exemplary embodiment, the first conductive plates 166 include titanium nitride, e.g., at least one layer of titanium nitride layer.

In an exemplary embodiment, operation of the DRAM device may include applying a pull-in voltage to the word lines 152, and applying an attractive force to the first conductive plates 166. The conductive plate 166 may move downward to contact the first conductive pads 150 based on the interaction between the pull-in voltage and the attractive force to form the second state of the DRAM device. In the second state, the first conductive plates 166 may not contact the word lines 152 because the first distance d1 is larger than the second distance d2. When the first conductive plates 166 contacts the corresponding first conductive pads 150, e.g., via a protrusion on the blades 166b, an electrical signal applied to the bitlines 105 may be transferred to the capacitors 132, e.g., through the first plug 146 and corresponding conductive plates 166. In the second state, data may be stored in the capacitors 132, or the data stored in the capacitors 132 may be output through the bitlines 105.

The first conductive plates 166 and the first conductive pads 150 may not contact each other, e.g., be spaced apart, in a standby state, e.g., the first state, in which data is not written or read. In the first state, the capacitors 132 may not be electrically connected to other elements of the DRAM device, e.g., the bitlines 105 and the word lines 152, and the charges stored in the capacitors 132 may not leak. Accordingly, the DRAM device may have good data retention characteristics.

In an exemplary embodiment, the word lines 152 may be arranged below lateral end portions of the blades 166b, e.g., the farthest portion of the blades 166b from the anchors 166a fixed to the second conductive pads 154. During the second state, attractive forces applied to the first conductive plates 166 may efficiently move the first conductive plates 166 downward. According to an exemplary embodiment, the conductive plates 166 may move downward even when a small amount of a pull-in voltage is applied to the word lines 152 and/or when an overlapping area between the first conductive plates 166 and the word lines 152 is small. Accordingly, the DRAM device may have an improved integration degree.

The DRAM device may include a conductive pad arranged below middle portions of end portions of the blade 166b, and a word line arranged between the first plug 146 and the conductive pad. In this configuration, an attractive force applied to the first conductive plate 166 may not efficiently move the first conductive plate 166 downward because the attractive force may not have a sufficient effect on a central portion of the blade 166b. Accordingly, a higher pull-in voltage or a larger overlapping area may be necessary to effectively move the first conductive plate 166 toward the conductive pad. As a result, the DRAM device may require a higher pull-in voltage and/or have a lower integration degree. Additionally, the attractive force may be concentrated on the central portion of the blade 166b so that the first conductive plate 166 may be attacked or damaged.

In an exemplary embodiment including the word lines 152 arranged below end portions, e.g., lateral end portions, of the blade 166b, the attractive force may not be concentrated on a specific portion of the blade 166b. Thus, the first conductive plate 166 may not be attacked.

The capacitors 132 may extend in the first direction parallel to the bitlines 105, and the capacitors 132 may be disposed under the word lines 152. The capacitors 132 may be larger, e.g., occupy more area, than capacitors that are arranged beside the word lines 152. Thus, the capacitors 132 may have an improved, e.g., higher, capacitance and the DRAM device may have good data retention characteristics.

FIGS. 4 to 15 illustrate cross-sectional views of an exemplary method of manufacturing the DRAM device of FIG. 1. FIGS. 16 to 20 illustrate top views of an exemplary method of manufacturing the DRAM device of FIG. 1.

Referring to FIG. 4, an insulation layer (not shown), a first conductive layer, and a hard mask layer may be sequentially formed on the substrate 100. The first conductive layer may be formed using, e.g., polysilicon and/or tungsten silicide. The hard mask layer may be formed using, e.g., silicon nitride.

The hard mask layer may be patterned to form a plurality of first hard masks 106 that are arranged extending in a second direction, e.g., the hard mask 106 may be elongated in the second direction of the substrate. The first hard masks 106 may be arranged in the first direction, e.g., parallel to adjacent first hard masks 106 in the first direction. The first hard masks 106 may be parallel to the first conductive layer in the first direction. The first conductive layer may be etched using the hard mask 106 as an etching mask to form a plurality of bitlines 105. The bitline structures may include the bitlines 105 and the corresponding first hard masks 106 formed on the insulation layer. In an exemplary embodiment, the bitlines 105 may have a stacked structure including a polysilicon layer pattern 102 and a tungsten silicide layer pattern 104.

A first insulating interlayer 108 may be formed on the substrate 100 to cover the bitline structures. The first insulating interlayer 108 may be formed using a silicon oxide deposition process, e.g., by using a chemical vapor deposition (CVD) process.

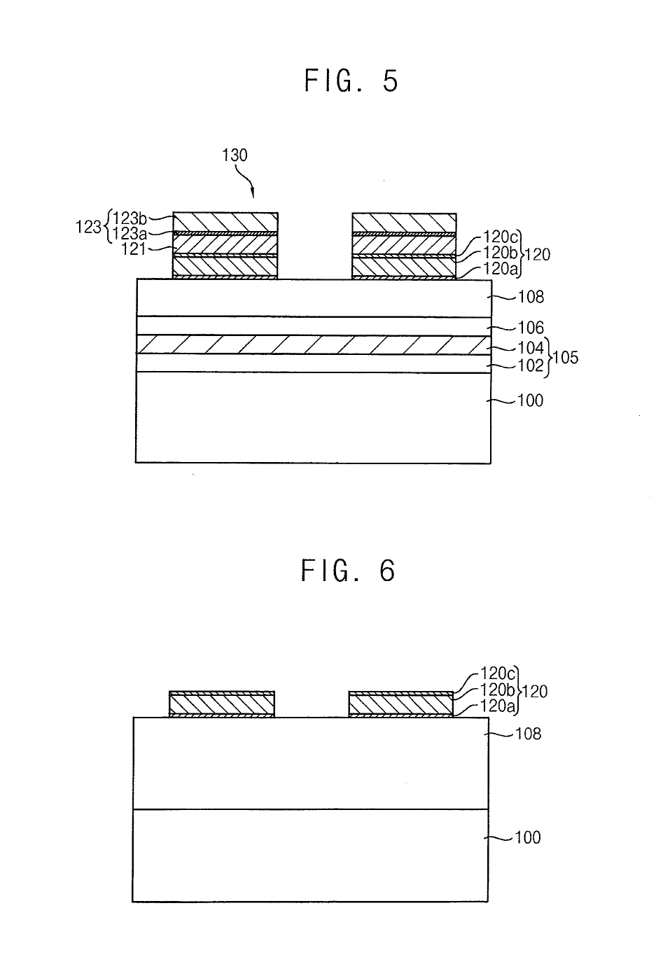

Referring to FIGS. 5 and 16, a first electrode layer, a dielectric layer, and a second electrode layer may be formed on the first insulating interlayer 108. The first and second electrode layers may include a metal. The dielectric layer may include a metal oxide having a high dielectric constant.

In an exemplary embodiment, forming the first electrode layer may include, e.g., sequentially depositing a first barrier metal layer, a metal layer, e.g., a tungsten layer, and a second barrier metal layer, e.g., a titanium nitride layer, on the first insulating interlayer 108. The first barrier metal layer may be formed using titanium, e.g., a titanium nitride layer. Forming the dielectric layer may include, e.g., depositing at least one of aluminum oxide, zirconium oxide, hafnium oxide, tantalum oxide, combinations thereof, etc, on the first electrode layer. For example, the dielectric layer may be formed by sequentially depositing zirconium oxide, aluminum oxide, and zirconium oxide. Forming the second electrode layer may include, e.g., sequentially deposited a barrier metal layer, e.g., a titanium nitride layer, and a metal layer, e.g., a tungsten layer, on the dielectric layer.

The second electrode layer, the dielectric layer, and the first electrode layer may be etched using a first mask (not shown) as an etching mask to form a plurality of intermediate capacitors 130 arranged in, e.g., the first direction. The intermediate capacitors 130 may extend in, e.g., the second direction that may be perpendicular to the first direction. The intermediate capacitors 130 may include the first electrode 120, an intermediate dielectric layer pattern 121, and an intermediate second electrode 123 sequentially stacked on the first insulating interlayer 108.

In an exemplary embodiment, the first electrode 120 may be formed to have a stacked structure including a barrier layer pattern 120a, a tungsten layer pattern 120b, and a titanium nitride layer pattern 120c. The intermediate second electrode 123 may be formed to have a stacked structure including a titanium nitride layer pattern 123a and a tungsten layer pattern 123b.

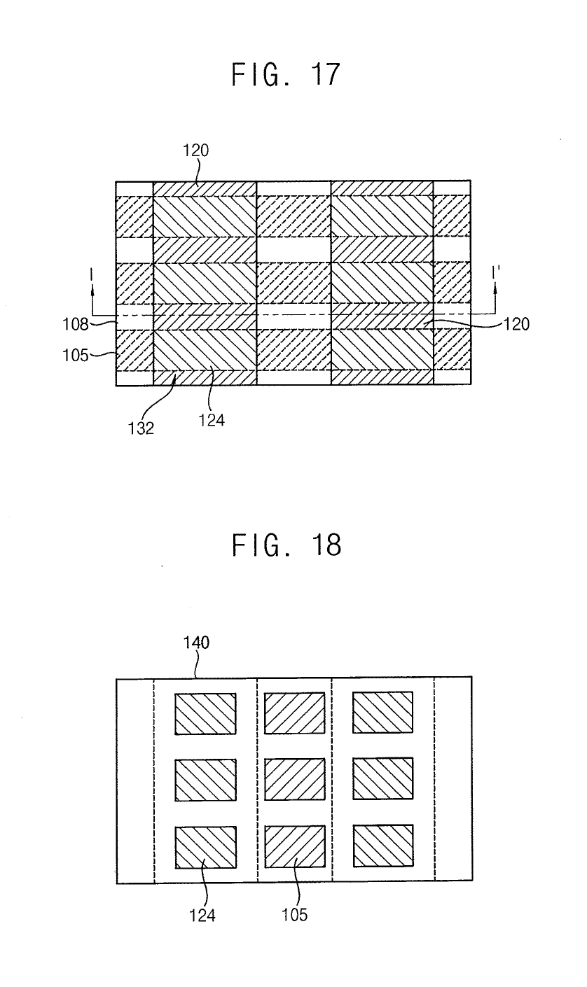

FIG. 6 illustrates a cross-sectional view of FIG. 17 taken along the line I-I′. Therefore, FIG. 6 illustrates a cross-sectional view the DRAM device of FIG. 1.

Referring to FIGS. 6 and 17, the intermediate second electrode 123 and the intermediate dielectric layer pattern 121 may be etched using a second mask (not shown) as an etching mask to form a plurality of second electrodes 124 and a plurality of dielectric layer patterns 122, respectively. The second electrodes 124 and the dielectric layer patterns 122 may be island-shaped. According to an exemplary embodiment, the sequentially stacked first electrode 120, dielectric layer patterns 122, and second electrodes 124 may form a plurality of capacitors 132. The plurality of capacitors 132 may be formed on the first insulating interlayer 108.

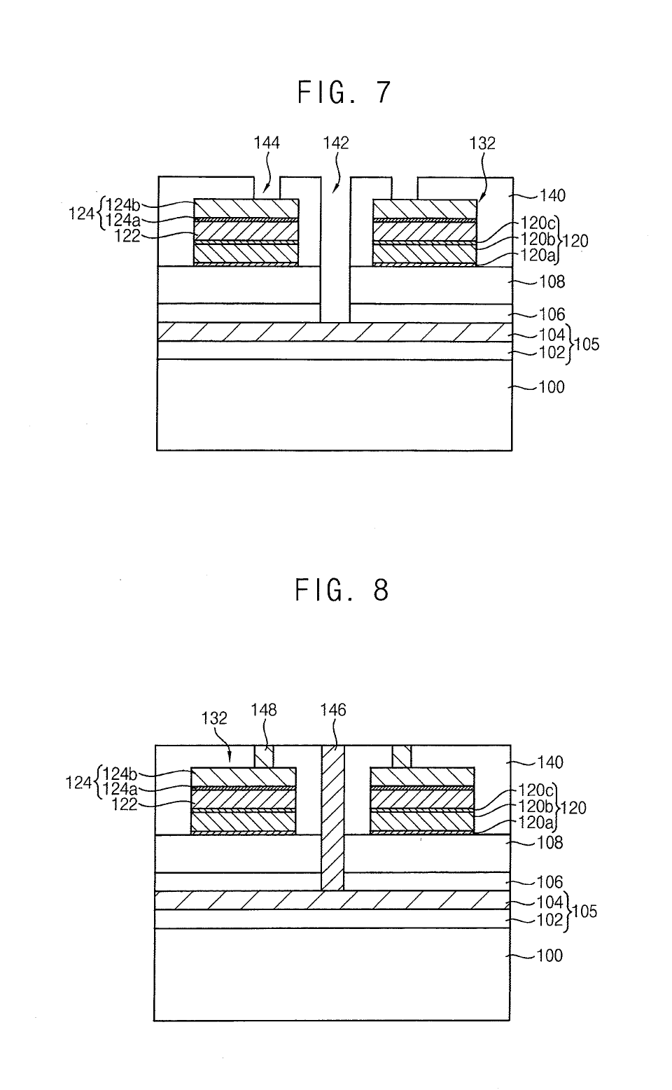

Referring to FIGS. 7 and 18, a second insulating interlayer 140 may be formed on the first insulating interlayer 108 to cover the capacitors 132. The second insulating interlayer 140 may be formed by depositing silicon oxide, e.g., by a CVD process. In an exemplary embodiment, an upper portion of the second insulating interlayer 140 may be planarized to expose a top surface of the second electrode 124. In an exemplary embodiment, additional insulating interlayer (not shown) may be formed on the second insulating interlayer 140 and the second electrode 124, and a portion of the additional insulating interlayer may be removed to expose a top surface of the second electrode 124. The second insulating interlayer 140 may include a plurality of layers sequentially stacked.

The first and second insulating interlayers 108 and 140 and the first hard mask 106 may be etched using a second hard mask (not shown) as an etching mask to form a plurality of first contact holes 142. The second insulating interlayer 140 may be etched using an etching mask, e.g., the second hard mask, to form a plurality of first openings 144. The first contact holes 142 may extend through the first and second insulating interlayers 108 and 140 and the first hard mask 106. The first contact holes 142 may expose the bitlines 105. The first contact holes 142 may expose portions of the bitlines 105 that do not overlap the capacitors 132. The plurality of first openings 144 may extend through an upper portion of the second insulating interlayer 140. The first openings 144 may expose the capacitors 132. The first openings 144 may expose portions of the second electrodes 124, e.g., metal layer 124b.

Referring to FIG. 8, a conductive material may be deposited in the first contact holes 142 and the first openings 144 to form a second conductive layer. For example, the conductive material may be deposited on the bitlines 105, the second electrodes 124, and the second insulating interlayer 140 to substantially fill the first contact holes 142 and the first openings 144 to form in the second conductive layer. An upper portion of the second conductive layer may be planarized until a top surface of the second insulating interlayer 140 is exposed to form a plurality of first plugs 146 and a plurality of lower conductive pads 148 filling the first contact holes 142 and the first openings 144, respectively.

In an exemplary embodiment, the second conductive layer may be formed using a metal, e.g., tungsten. Before forming the second conductive layer, a barrier layer (not shown) may be further formed on inner walls of the first contact holes 142 and the first openings 144. The barrier layer may be formed using titanium, e.g., a titanium nitride layer.

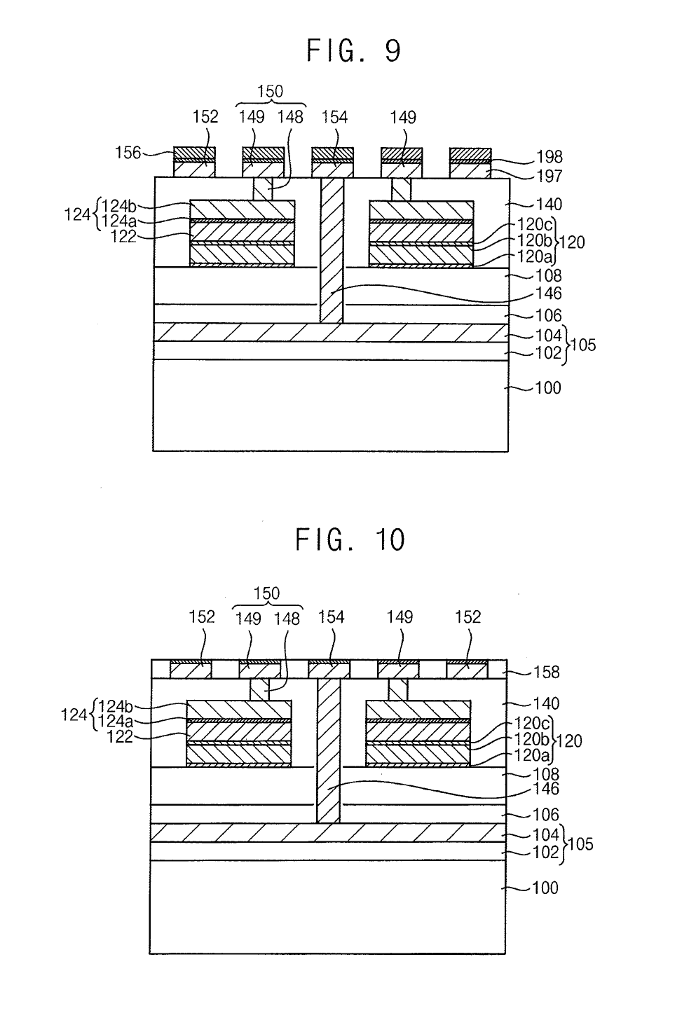

Referring to FIG. 9, a third conductive layer may be formed on the second insulating interlayer 140, the first plugs 146, and the lower conductive pads 148. The third conductive layer may be formed using a metal.

In an exemplary embodiment, the third conductive layer may be formed to have a stacked structure including a lower layer 197 and an upper layer 198. The lower layer 197 may be formed using, e.g., a material substantially the same as that of the first plugs 146 and/or the lower conductive pads 148. Thereby, the lower layer 197 of the third conductive layer may have good adhesion to the underlying layers and/or reduced resistance. For example, the lower layer 197, the first plugs 146, and the lower conductive pads 148 may be formed using a material that includes tungsten.

The upper layer 198 of the third conductive layer may be formed using, e.g., a material substantially the same as that of the first conductive plate 166. Thereby, the upper layer 198 may have good adhesion. For example, the upper layer 198 and the first conductive plate 166 may be formed using a material that includes titanium nitride.

A third hard mask 156 may be formed on the third conductive layer. The third conductive layer, e.g., the upper and lower layers, may be etched using the third hard mask 156 to form a plurality of upper conductive pads 149, a plurality of second conductive pads 154, and a plurality of word lines 152. In an exemplary embodiment, the upper conductive pads 149 and the second conductive pads 154 may be island-shaped, and the word lines 152 may be formed to have a linear shape extending in the second direction. The upper conductive pads 149 may be formed on the lower conductive pads 148, and the upper conductive pads 149 may overlap substantially an entire area of an upper surface of the lower conductive pads 148. The lower and upper conducive pads 148 and 149 may be referred to as first conductive pads 150. The second conductive pads 154 may be formed on the first plugs 146, and the second conductive pads 154 may overlap substantially an entire area of an upper surface of the first plugs 146.

According to an exemplary embodiment, the second conductive pads 154, the first conductive pads 150, and the word lines 152 may be sequentially formed on the second insulating interlayer 140. Thereby, the first conductive pad 150 may be arranged between an adjacent second conductive pad 154 and an adjacent word line 152.

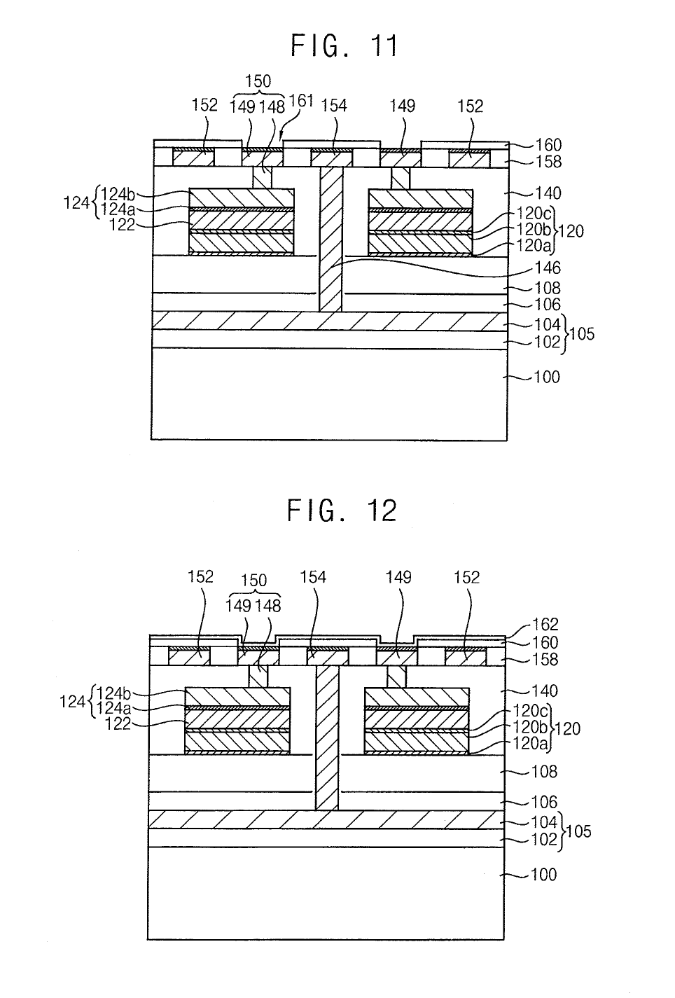

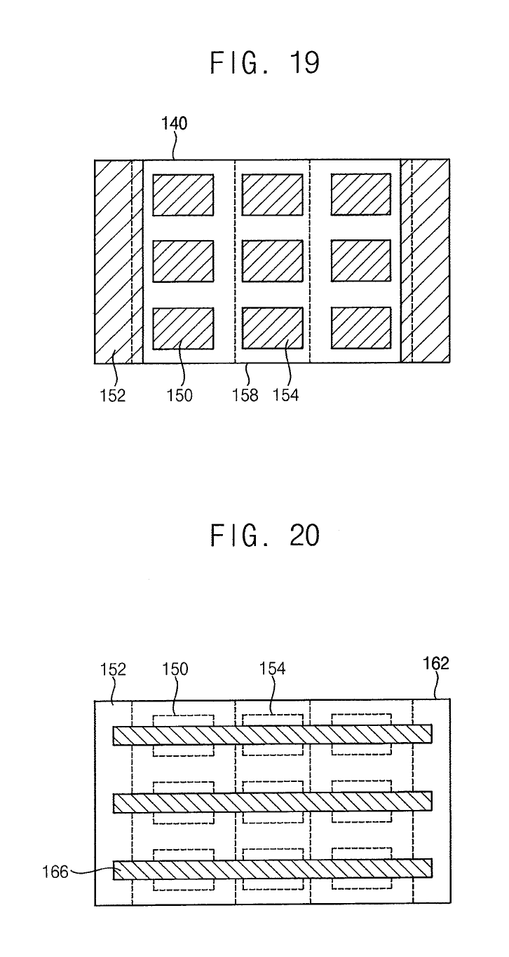

Referring to FIGS. 10 and 19, a third insulating interlayer 158 may be formed on the second insulating interlayer 140 to cover the third hard mask 156, the first and second conductive pads 150 and 154, and the word lines 152. The third insulating interlayer 158 may be formed by depositing silicon oxide, e.g., by a high density plasma chemical vapor deposition (HDP-CVD) process. An upper portion of the third insulating interlayer 158 may be planarized until top surfaces of the first and second conductive pads 150 and 154 and the word lines 152 are exposed. An upper surface of the third insulating interlayer 158, upper surfaces of the first and second conductive pads 150 and 154, and upper surfaces of the word lines 152 may be substantially co-planar. During the planarization process, the third hard mask 156 may be removed.

Referring to FIG. 11, a first sacrificial layer 160 may be formed on the third insulating interlayer 158, the first and second conductive pads 150 and 154, and the word lines 152. The first sacrificial layer 160 may be deposited using, e.g., an atomic layer deposition (ALD) process. The first sacrificial layer 160 may be formed using, e.g., a material having an etching selectivity with respect to a fourth conductive layer formed thereon in a subsequent step. For example, the first sacrificial layer 160 may be formed using, e.g., polysilicon, silicon oxide, combinations thereof, etc. The first sacrificial layer 160 may be formed to have a less dense structure than that of the third insulating interlayer 158, e.g., by forming the first sacrificial layer 160 using silicon oxide. Thereby, the first sacrificial layer 160 may be etched faster than the third insulating interlayer 158.

Thereafter, the first sacrificial layer 160 may be etched to selectively expose underlying layers. For example, the first sacrificial layer 160 may be etched to partially remove portions thereof to form second openings 161. The second openings 161 may expose the first conductive pads 150. The second openings 161 may expose substantially an entire area of the upper surface of the first conductive pads 150. The second openings 161 may substantially expose only the first conductive pads 150.

Referring to FIG. 12, a second sacrificial layer 162 may be formed on, e.g., directly on, the first sacrificial layer 160 and the exposed portions of the first conductive pads 150. The second sacrificial layer 162 may be formed using a material having an etching selectivity with respect to the fourth conductive layer formed thereon in a subsequent step. The second sacrificial layer 162 may be formed using a material substantially the same as or a material different than that of the first sacrificial layer 160. The second sacrificial layer 162 may be deposited using, e.g., an ALD process.

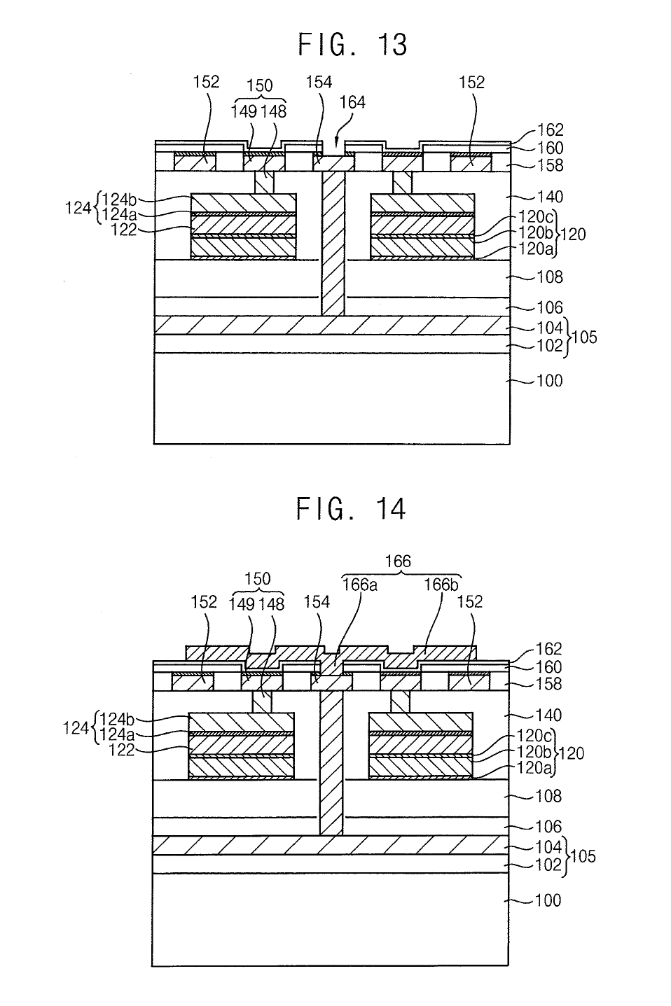

Referring to FIG. 13, the first and second sacrificial layers 160 and 162 may be selectively etched to expose underlying layers. For example, the first and second sacrificial layers 160 and 162 may be etched to partially remove portions thereof to form third openings 164. The third openings 164 may expose portions of the second conductive pads 154. The third openings 164 may substantially expose only the second conductive pads 154. The third openings 164 may be spaced apart from the second openings 161.

Referring to FIGS. 14 and 20, the fourth conductive layer may be formed on the second sacrificial layer 162 and the exposed portions of the second conductive pads 154. The fourth conductive layer may substantially fill the third openings 164. The fourth conductive layer may be formed using a material that may move according to the change of an electric field. The fourth conductive layer may have an elastic force and a restoring force. For example, the fourth conductive layer may be formed using at least one of titanium nitride, CNT, titanium, combinations thereof, etc. In an exemplary embodiment, the fourth conductive layer may be formed using titanium nitride.

The fourth conductive layer may be patterned to form a plurality of first conductive plates 166 overlapping the first conductive pads 150 and the word lines 152. The first conductive plates 166 may be arranged in the second direction of the substrate 100, e.g., parallel to adjacent first conductive plates 166. The first conductive plates 166 may extend in the first direction, e.g., the conductive plates 166 may be elongated in the first direction of the substrate 100.

The first conductive plate 166 may have an anchor 166a and at least one blade 166b. The anchor 166a may contact, e.g., be formed directly on, the second conductive pad 154. The blades 166b may overlap the corresponding first conductive pads 150 and word lines 152. The bladed 166b may have an unevenness shape, e.g., the blades 166b may have protrusion portions overlapping the first conductive pad 150 and recess portions overlapping the word lines 152.

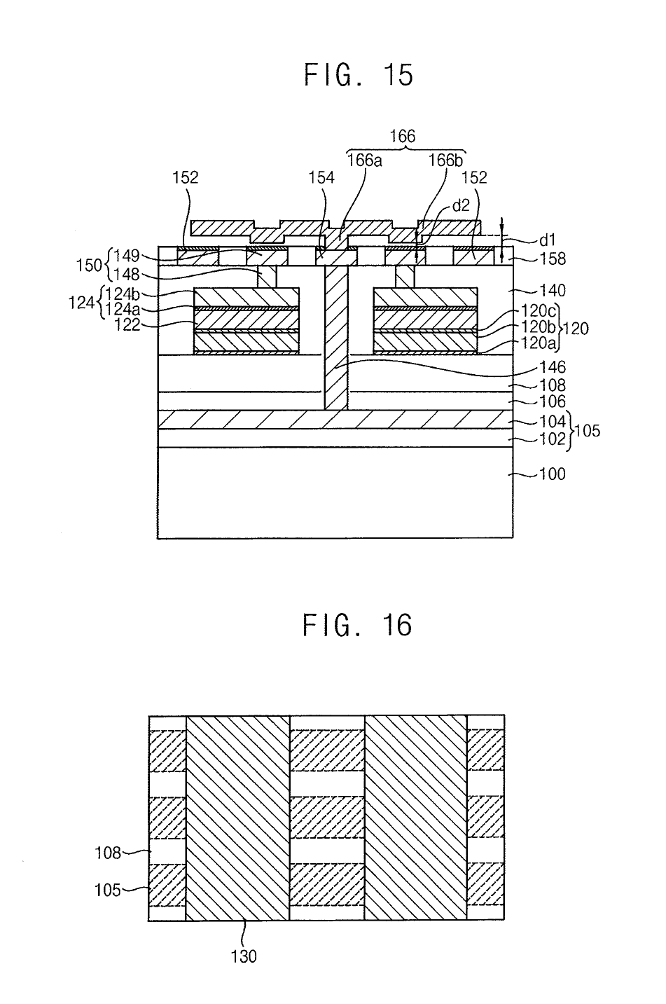

Referring to FIG. 15, to complete the DRAM device, the first and second sacrificial layers 160 and 162 may be removed. When the first and second sacrificial layers 160 and 162 include substantially the same material, the first and second sacrificial layers 160 and 162 may be removed by one etching process. When the first and second sacrificial layers 160 and 162 include different materials, the first and second sacrificial layers 160 and 162 may be removed by two etching processes. Removal of the sacrificial layers 160 and 162 may be performed by at least one of a wet etching process, a dry etching process, combinations thereof, etc.

In an exemplary embodiment, the first and second sacrificial layers 160 and 162 may be formed using substantially a same material as that of the third insulating interlayer 158. The third insulating interlayer 158 may have a denser structure than those of the first and second sacrificial layers 160 and 162. Thereby, third insulating interlayer 140 may have a lower etching rate. Thus, even though the third insulating interlayer 158 may be partially removed when the first and second sacrificial layers 160 and 162 are etched, the third insulating interlayer 158 may not be substantially removed, i.e., not removed too much.

The first conductive plates 166 and the word lines 152 may be spaced apart from each other by the removal of the first and second sacrificial layers 160 and 162. The first conductive plates 166 and the first conductive pads 150 may be spaced apart from each other by the removal of the first and second sacrificial layers 160 and 162. Referring to FIG. 15, in an exemplary embodiment, the first distance between the first conductive plates 166 and the word lines 152 may be larger than the second distance between the first conductive plates 166 and the first conductive pads 150.

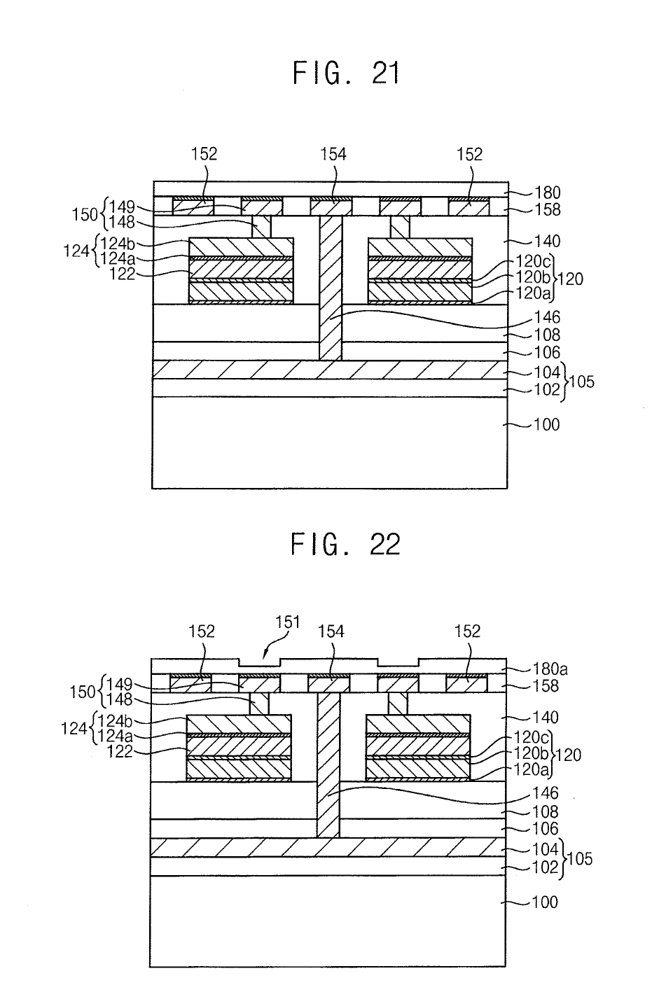

FIGS. 21 and 22 illustrate cross-sectional views of an exemplary method of manufacturing the DRAM device of FIG. 1. The method for manufacturing the DRAM device as illustrated in FIGS. 21 and 22 may be substantially similar to the method illustrated with reference to FIGS. 4 to 20. Thus, like reference numerals refer to like elements, and repetitive explanations are omitted herein.

Process steps substantially similar to those illustrated with reference to FIGS. 4 to 10 may be performed to form the resultant structure of FIG. 10.

Referring to FIG. 21, the process for forming first conductive plates 166 may include forming a first intermediate sacrificial layer 180. The first intermediate sacrificial layer 180 may be formed on the third insulating interlayer 158, the first and second conductive pads 150 and 154, and the word lines 152. The first intermediate sacrificial layer 180 may be formed using a material having an etching selectivity with respective to a fifth conductive material formed thereon in a subsequent step.

For example, the first intermediate sacrificial layer 180 may be fanned using polysilicon, silicon oxide, combinations thereof, etc. The first inteimediate sacrificial layer 180 may be deposited on the substrate using, e.g., an ALD process. According to an exemplary embodiment, when the first intermediate sacrificial layer 180 is formed using silicon oxide, the first intermediate sacrificial layer 180 may have a less dense structure than that of the third insulating interlayer 158. The less dense first intermediate sacrificial layer 180 may be etched faster than the underlying third insulating interlayer 158.

Referring to FIG. 22, the first intermediate sacrificial layer 180 may be transformed into a third sacrificial layer 180a by an etching process. Upper portions of the first intermediate sacrificial layer 180 may be removed using a photoresist pattern (not shown) as an etching mask to form recesses 151 therein. The recesses 151 may overlap the first conductive pads 150, and the recesses 151 may not expose the first conductive pads 150, i.e., the recesses 151 may not be through-holes. Thereby, the third sacrificial layer 180a may have a thickness at portions over the first conductive pads 150 that is smaller than at other portions thereof After the recesses 151 are formed, the photoresist pattern may be removed.

The DRAM device of FIG. 1 may be manufactured using process steps substantially similar to those illustrated with reference to FIGS. 13 to 15, e.g., to form the first conductive plates 166 using a fifth conductive material and to remove the third sacrificial layer 180.

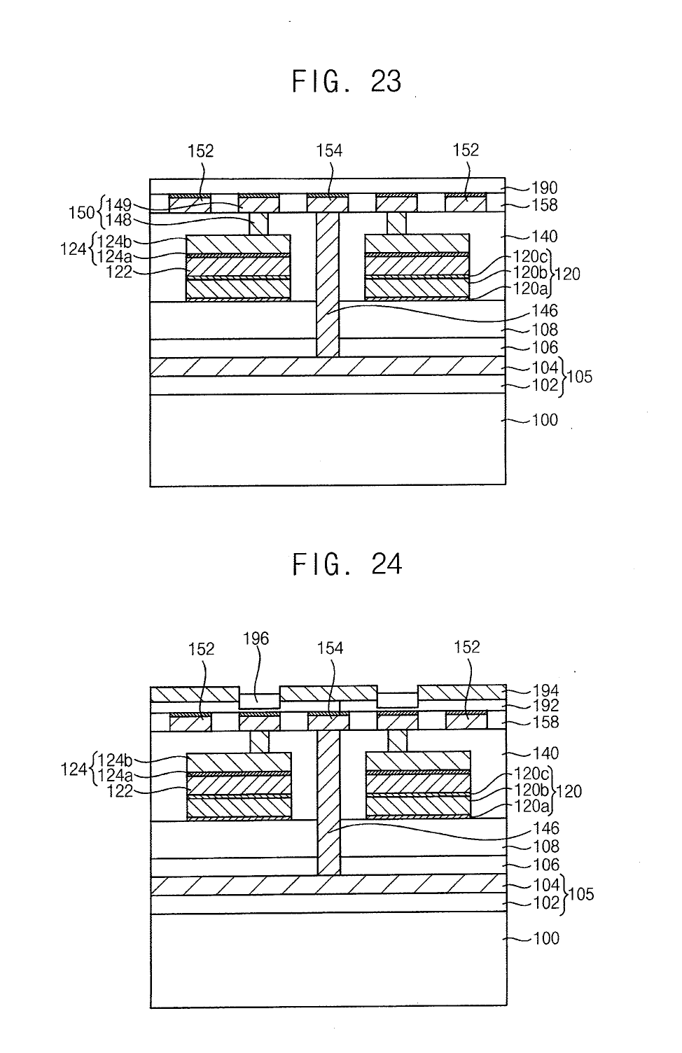

FIGS. 23 to 25 illustrate cross-sectional views of an exemplary method of manufacturing the DRAM device of FIG. 1. The method for manufacturing the DRAM device as illustrated in FIGS. 23 to 25 may be substantially similar to the method illustrated with reference to FIGS. 4 to 20 except for processes for forming first conductive plates. Thus, like reference numerals refer to like elements, and repetitive explanations are omitted herein.

Process steps substantially similar to those illustrated with reference to FIGS. 4 to 10 may be performed to form the resultant structure of FIG. 10.

Referring to FIG. 23, the process for forming first conductive plates 166 may include forming a second intermediate sacrificial layer 190 on the third insulating interlayer 158, the first and second conductive pads 150 and 154, and the word lines 152. The second intermediate sacrificial layer 190 may be formed using a material having an etching selectivity with respect to a sixth conductive material formed thereon in a subsequent step.

For example, the first intermediate sacrificial layer 190 may be formed using polysilicon, silicon oxide, combinations thereof, etc. The first intermediate sacrificial layer 190 may be deposited on the substrate using, e.g., an ALD process. According to an exemplary embodiment, the first intermediate sacrificial layer 190 may be formed of polysilicon.

Referring to FIG. 24, a fourth hard mask 194 may be formed on the second intermediate sacrificial layer 190. The fourth hard mask 194 may overlap the second conductive pads 154 and the word lines 152. The fourth hard mask 194 may expose portions of the second intermediate sacrificial layer 190 on the first conductive pads 150. According to an exemplary embodiment, the fourth hard mask 194 may be formed of silicon nitride.

The exposed portions of the second intermediate sacrificial layer 190 may be oxidized to form a silicon oxide layer 196 on the second intermediate sacrificial layer 190. Thus, the second intermediate sacrificial layer 190 may be transformed into a fourth sacrificial layer 192 having a smaller thickness at portions over the first conductive pads 150, i.e., regions where the silicon oxide layer 196 is formed, than that at other portions thereof.

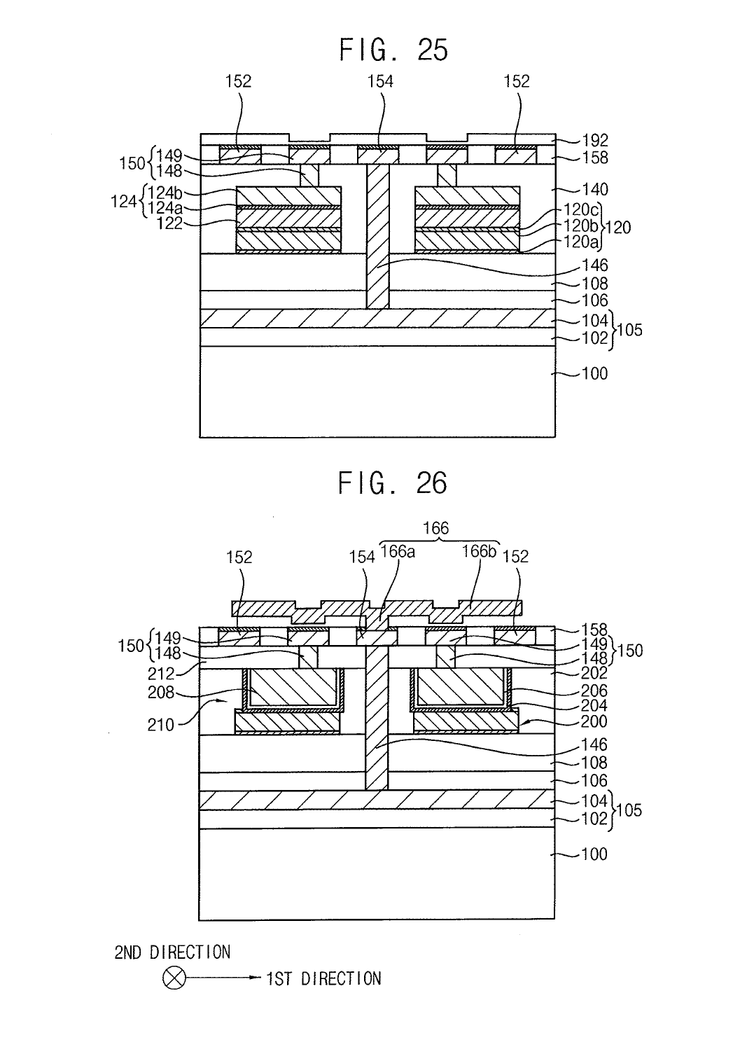

Referring to FIG. 25, the silicon oxide layer 196 and the fourth hard mask 194 may be removed. The removal may be performed by, e.g., a wet etching process. The second intermediate sacrificial layer 190 may not be removed during this process step.

The DRAM device of FIG. 1 may be manufactured using process steps substantially similar to those illustrated with reference to FIGS. 13 to 15, e.g., to form the first conductive plates 166 using the sixth conductive material and to remove the fourth sacrificial layer 192.

FIG. 26 illustrates a cross-sectional view of DRAM device in accordance with an exemplary embodiment. The DRAM device of FIG. 26 may have substantially the same shape as that DRAM device of FIG. 1. In an exemplary embodiment, the DRAM device of FIG. 26 may include capacitors 210 having a different shape than capacitors 132. The method of manufacturing the DRAM device as illustrated in FIG. 26 may be substantially similar to the method illustrated with reference to FIGS. 4 and 7-15. Thus, like reference numerals refer to like elements, and repetitive explanations are omitted herein.

Referring to FIG. 26, a plurality of bitline structures may be formed on the substrate 100. Each bitline structure may extend in the first direction, e.g., be elongated in the first direction. A first insulating interlayer 108 covering the bitline structures may be formed on the substrate 100.

A plurality of electrode lines 200 may be formed on the first insulating interlayer 108 in the first direction. Each of the electrode lines 200 may extend in the second direction, e.g., be elongated in the second direction. The second direction may be perpendicular to the first direction. The electrode lines 200 may be arranged in the first direction, e.g., arranged parallel to adjacent electrode lines 200 in the first direction.

The plurality of capacitors 210 may be formed on the electrode lines 200. The capacitor 210 may include a first electrode 204, a dielectric layer pattern 206, and a second electrode 208. The dielectric layer pattern 206 may be on the first electrode 204, and the second electrode 208 may be on the dielectric layer pattern 206. In an exemplary embodiment, the capacitors 210 may have a cylindrical shape. For example, the first electrode 204 and the dielectric layer pattern 206 may have a cylindrical shape, and the second electrode 208 may fill a space formed by the cylindrical dielectric layer 206. In another exemplary embodiment, the capacitors 210 may have a rectangular-like shape. For example, the first electrode 204 and the dielectric layer 206 may be formed to have a lower surface and lateral side surfaces. The dielectric layer 206 may substantially overlap the entire first electrode 204. Thereby, the dielectric layer 206 may include a lower surface and lateral side surfaces. The second electrode 208 may substantially fill a space between the lateral side surfaces of the first electrode 204 and the dielectric layer 206.

A second insulating interlayer 202 surrounding the electrode lines 200 and the capacitors 210, may substantially fill spaces between the capacitors 210 and the electrode lines 200. A third insulating interlayer 212 may be formed on the second insulating interlayer 202 and the capacitors 210.

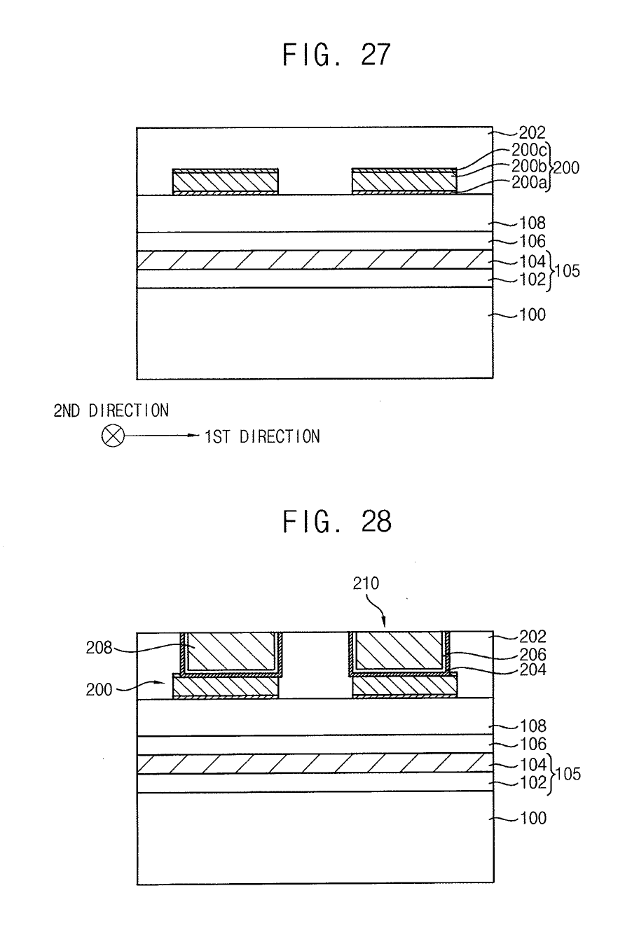

FIGS. 27 to 29 illustrate cross-sectional views of an exemplary a method of manufacturing the DRAM device of FIG. 26. The method for manufacturing the DRAM device of FIG. 26 may be substantially similar to the method illustrated with reference to FIGS. 4 and 7-15. Thus, like reference numerals refer to like elements, and repetitive explanations are omitted herein.

Process steps substantially similar to those illustrated with reference to FIG. 4 may be performed to form the bitline structures and first insulating interlayer 108. Thereafter, electrode lines 200 and capacitors 210 may be formed on the first insulating interlayer 108.

Referring to FIG. 27, the plurality of electrode lines 200 may be formed on the first insulating interlayer 108, the electrode lines 200 may be arranged in the first direction. Each electrode line 200 may extend in the second direction, e.g., the electrode line 200 may be elongated in the second direction. The second direction may be perpendicular to the first direction. In an exemplary embodiment, the electrode lines 200 may have a stacked structure including barrier metal layer patterns 200a, metal layer patterns 200b, and barrier layer patterns 200c. A second insulating interlayer 202 may be formed on the first insulating interlayer 108 to cover the electrode lines 200.

Referring to FIG. 28, upper portions of the second insulating interlayer 202 may be removed to form openings (not shown) exposing the electrode lines 200. A first electrode layer may be formed on inner walls of the openings and the second insulating interlayer 202. A dielectric layer may be formed on the first electrode layer. A second electrode layer may be formed on the dielectric layer to fill the remaining portions of the openings.

To form capacitors 210, upper portions of the first and second electrode layers and the dielectric layer may be planarized until a top surface of the second insulating interlayer 202 is exposed. The capacitors 210 may include a first electrode 204 formed from the first electrode layer, a dielectric layer pattern 206 formed from the dielectric layer, and a second electrode 208 formed from the second electrode layer.

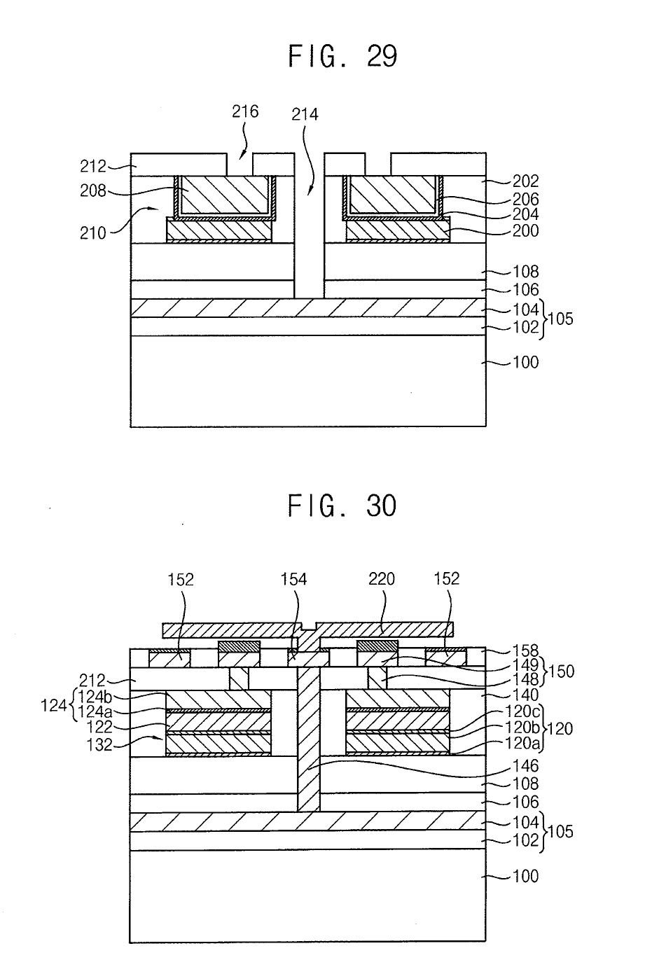

Referring to FIG. 29, a third insulating interlayer 212 may be formed on the second insulating interlayer 202 and the capacitors 210. The hard mask 106 and the first, second, and third insulating interlayers 108, 202, and 212 may be partially removed to form first contact holes 214 therethrough that expose corresponding bitlines 105. The third insulating interlayer 212 may be partially removed to form first openings 216 therethrough exposing the corresponding second electrodes 208 of capacitors 210. Process steps substantially similar to those illustrated with reference to FIGS. 8 to 15 may be performed to complete the DRAM device of FIG. 26.

FIG. 30 illustrates a cross-sectional view of an exemplary embodiment of a DRAM device. The method of manufacturing the DRAM device of FIG. 30 may be similar to the method illustrated with reference to the DRAM device of FIG. 1. Thus, like reference numerals refer to like elements, and repetitive explanations are omitted herein.

Referring to FIG. 30, the DRAM device may include a second conductive plate 220. The second conductive plates 220 may include substantially even shaped blades, e.g., flat blades. The first conductive pad 150 may have a top surface higher than the top surface of the second conductive pad 154 and the top surface of the word line 152.

The plurality of second conductive plates 220 may be formed on the second conductive pads 154. The second conductive plates 220 may extend over the first conductive pads 150 and the word lines 152 in the first direction. The first conductive pads 150 have the higher top surface, so that a distance between the first conductive pads 150 and the corresponding second conductive plates 220 may be smaller than the distance between the word lines 152 and the corresponding second conductive plates 220.

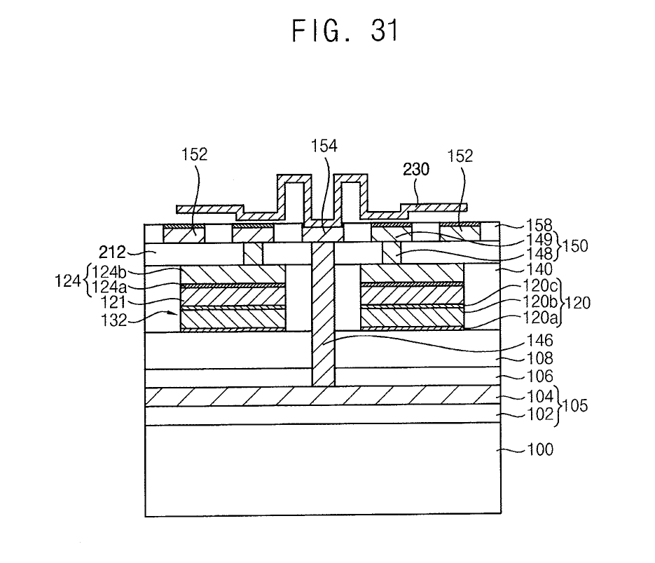

FIG. 31 illustrates a cross-sectional view of an exemplary embodiment of a DRAM device. The method of manufacturing the DRAM device of FIG. 31 may be substantially similar to the method illustrated with reference to the DRAM device of FIG. 1. Thus, like reference numerals refer to like elements, and repetitive explanations are omitted herein.

Referring to FIG. 31, the DRAM device may include a third conductive plate 230. The third conductive plates 230 may have a bent shape. The plurality of third conductive plates 230 may be formed on the second conductive pads 154. The second conductive plates 230 may extend over the first conductive pads 150 and the word lines 152 in the first direction of the substrate 100.

The third conductive plates 230 may be bent, and a distance between the third conductive plate 230 and the first conductive pad 150 may be smaller than a distance between the third conductive plate 230 and the word line 152. In an exemplary embodiment, the third conductive plates 230 may include at least one protrusion between the first and second conductive pads 150 and 154. The third conductive plates 230 may include a first protrusion extending away from the substrate and/or a second protrusion extending toward the corresponding conductive pads 150. The at least one protrusion may reduce a tensile force at a portion of the third conductive plate 230 contacting the second conductive pads 154. Thus, even when a low pull-in voltage is applied, the third conductive plates 230 may be moved easily.

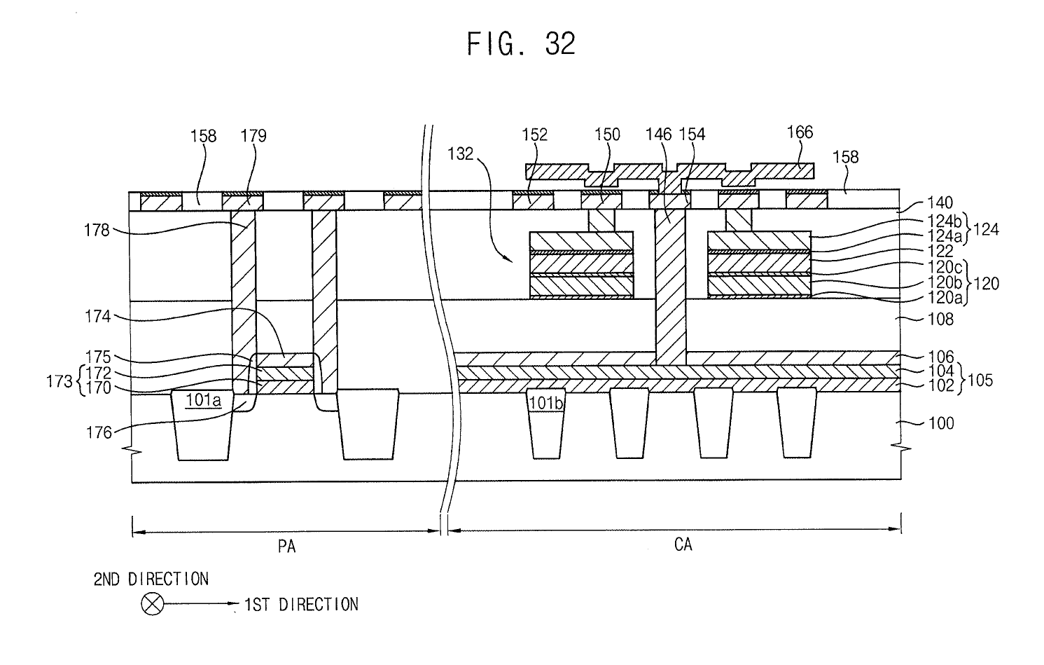

FIG. 32 illustrates a peripheral region PA and a cell region CA of a DRAM device in accordance with an exemplary embodiment. For ease of explanation, the method of forming the peripheral region PA is explained with reference to capacitors 132 in the cell region CA. However, the cell region CA may similarly include capacitors 210 according to an exemplary embodiment, and the method for forming the capacitors 210 may be substantially similar to the method illustrated with reference to FIGS. 27 and 28. The substrate 100 may include a single crystalline silicon substrate or a silicon-on-insulator (SOI) substrate.

Referring to FIG. 32, a first isolation layer 101a may be formed on the substrate 100 in the peripheral region PA. A second isolation layer 101b may be formed on a substrate 100 in the cell region CA. The second isolation layer 101b may serve as a dummy pattern that may prevent dishing in the cell region CA when the first isolation layer 101a is formed in the peripheral region PA. The second isolation layer 101b may not entirely isolate devices on the substrate 100.

In an exemplary embodiment, the cell array of the DRAM device of FIG. 1 may be formed on the substrate 100 in the cell region CA. A MOS transistor including a gate insulation layer (not shown), a gate electrode 173, and source/drain regions 176 may be formed on the substrate in the peripheral region PA. The gate electrode 173 may include a silicon layer 170 and a metal layer 172. The MOS transistor may serve as a switching device. A gate mask 174 may be formed on the gate electrode 173. The gate electrode 173 and the gate mask 174 may be referred to as a gate structure. Gate spacers 175 may be formed on sidewalls of the gate structure. The gate spacers 175 may overlap substantially an entire length of the sidewall of the gate structure including the gate electrode 173 and gate mask 174 sequentially stacked.

The gate structure may have a stacked structure, e.g., the stacked structure may be substantially the same as that of the bitline structure in the cell region. For example, the gate structure and the bitline structure may include the same materials and have a same thickness. The gate structures and the bitline structures may be simultaneously formed on the substrate 100.

The first and second insulating interlayers 108 and 140 may be formed in both the peripheral region PA and the cell region CA. The first insulating interlayer 108 may cover the MOS transistor in the peripheral region PA. The peripheral region PA may also include second plugs 178 formed through the first and second insulating interlayers 108 and 140. The second plugs 178 may be electrically connected to corresponding source/drain regions 176. The peripheral region PA may also include wirings 179 extending in the second direction of the substrate 100, e.g., the wirings 179 may be elongated in the second direction. The plurality of wirings 179 may be arranged in the first direction, e.g., the wirings 179 may be arranged parallel to adjacent wirings 179 in the first direction. The wirings 179 may be electrically connected to corresponding second plugs 178. The wirings 179 may be on the second insulating interlayer 140. The wirings 179 may be disposed in the same plane as at least the word lines 152 in the cell region.

According to an exemplary embodiment, the DRAM device of FIG. 32 may include the MOS transistor in the peripheral region PA and may include memory cells having electromechanical switches in the cell region CA. The DRAM device may have low leakage current, good data retention, and low operation voltage.

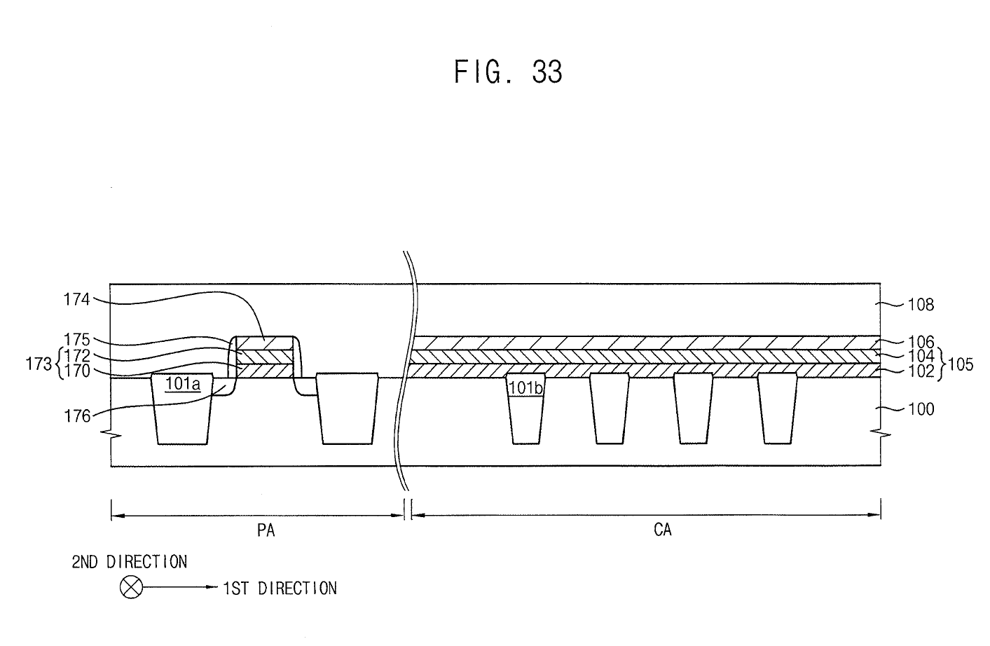

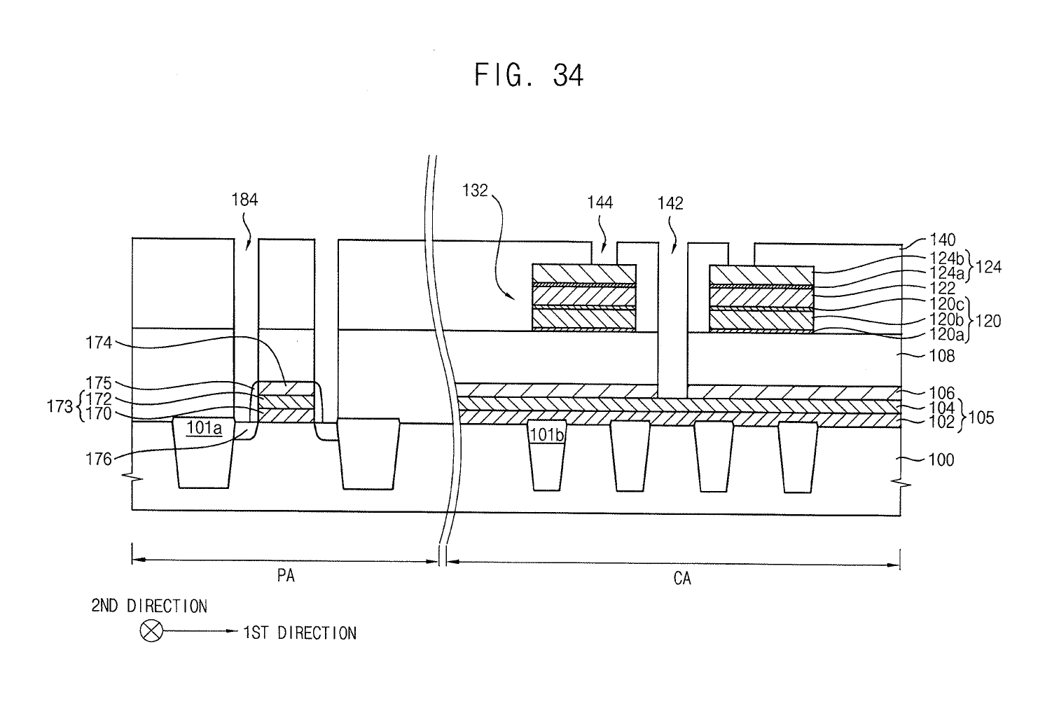

FIGS. 33 to 35 illustrate cross-sectional views of an exemplary a method of manufacturing the DRAM device of FIG. 32. The method for manufacturing at least the cell region CA may be substantially similar to the method illustrated with reference to FIGS. 4-20. Thus, like reference numerals refer to like elements, and repetitive explanations are omitted herein. For example, detailed explanations of the process steps for forming at least the capacitors 132, the first and second conductive pads 150 and 154, and the conductive plates are omitted herein.

Referring to FIG. 33, a substrate 100 having a cell region CA and a peripheral region PA may be provided. The substrate 100 may include a single crystalline silicon substrate or an SOI substrate. A first isolation layer 101a and a second isolation layer 101b may be formed on the substrate 100 in the peripheral region PA and the cell region CA, respectively. For example, a shallow trench isolation (STI) process or like process may be used to form the first and second isolation layers 101a and 101b. In an exemplary embodiment, upper portions of the substrate 100 may be removed to form trenches (not shown), and an insulating material may be filled into the trenches to form the first and second isolation layers 101a and 101b. In the STI process, the second isolation layer 101b may serve as a dummy pattern preventing dishing in the cell region CA.

An insulation layer (not shown), a first conductive layer, and a hard mask layer may be sequentially formed on the substrate 100. The insulation layer may serve as a gate insulation layer in the peripheral region PA. In an exemplary embodiment, the first conductive layer may be formed using polysilicon and/or tungsten silicide. The hard mask layer may be formed using silicon nitride.

The hard mask layer may be patterned to form a plurality of first hard masks 106 and a gate mask 175. The first hard masks 106 may be formed to extend in a first direction, and each gate mask 175 may be formed to extend in a second direction perpendicular to the first direction. In an exemplary embodiment, the first conductive layer may be etched using the hard mask 106 and the gate mask 175 as etching masks to form a plurality of bitlines 105 and a gate electrode 173 in the cell region CA and the peripheral region PA, respectively. Thus, bitline structures including the bitlines 105 and the first hard masks 106 may be formed on the insulation layer in the cell region CA, and the gate structure including the gate electrode 173 and the gate mask 175 may be formed on the gate insulation layer in the peripheral region PA.

A spacer layer may be formed on the substrate 100 to cover the gate structure and the bitline structures. The spacer layer may be anisotropically etched to form gate spacers 175 on sidewalls of the gate structure and bitline spacers (not shown) on sidewalls of the bitline structures.

Impurities may be implanted into upper portions of the substrate 100 in the peripheral region PA to form source/drain regions 176 adjacent to the gate structure. The source/drain regions 176 may be formed to have a light doped drain (LDD) structure.

As illustrated above, the gate structure and the bitline structure may be formed simultaneously to simplify the method of manufacturing the DRAM device. A first insulating interlayer 108 may be formed on the substrate 100 to cover the gate structure and the bitline structure.

Referring to FIG. 34, the plurality of capacitors 132 may be formed on the first insulating interlayer 108 in the cell region CA. For example, the method for forming the capacitors 132 may be substantially similar to the method illustrated with reference to FIGS. 5 and 6. For ease of explanation, the method of forming the peripheral region PA is explained with reference to capacitors 132 in the cell region CA. However, the cell region CA may similarly include capacitors 210 according to an exemplary embodiment, and the method for forming the capacitors 210 may be substantially similar to the method illustrated with reference to FIGS. 27 and 28.

The second insulating interlayer 140 may be formed on the first insulating interlayer 108 to cover the capacitors 132. The first and second insulating interlayers 108 and 140 may be removed to form fourth openings 184. The fourth openings 184 may expose the corresponding source/drain regions 176 in the peripheral region PA. The first and second insulating interlayers 108 and 140 and the first hard masks 106 may similarly be etched to form the first contact holes 142 exposing the corresponding bitlines 105 in the cell region CA. The second insulating interlayer 140 may be partially removed to form the first openings 144 exposing the capacitors 132.

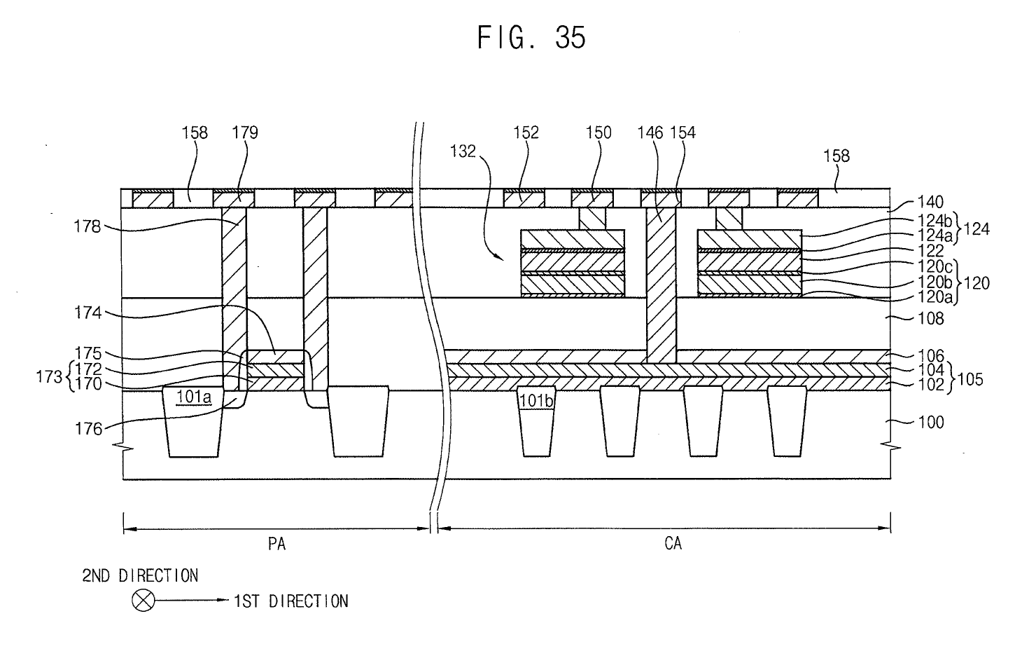

Referring to FIG. 35, a conductive material may be deposited on the bitlines 105, the capacitors 132, the source/drain regions 176, and the second insulating interlayer 140 to fill the first contact holes 142, the first openings 144, and the fourth openings 184 to form the second conductive layer. An upper portion of the resulting second conductive layer may be planarized until a top surface of the second insulating interlayer 140 is exposed. The planarized second conductive layer may form the plurality of first plugs 146, the plurality of lower conductive pads 148, and the plurality of second plugs 178 filling the respective first contact holes 142, the first openings 144, and the fourth openings 184.

A third conductive layer may be formed on the second insulating interlayer 140, the first plugs 146, the lower conductive pads 148, and the second plugs 178. The third conductive layer may be patterned to form second conductive pads 154, upper conductive pads 150, word lines 152, and wirings 179.

A third insulating interlayer 158 may be formed on the second insulating interlayer 140 to cover, e.g., the first and second conductive pads 150 and 154, the word lines 152, and the wirings 179. An upper portion of the third insulating interlayer 158 may be planarized until top surfaces of the first and second conductive pads 150 and 154, the word lines 152, and the wirings 179 are exposed.

The DRAM device of FIG. 32 may be manufactured by performing further process steps to form the plurality of conductive plates 166 on the second conductive pads 154. In an exemplary embodiment, the conductive plates 166 may be formed in the cell region CA and may not be formed in the peripheral region PA.

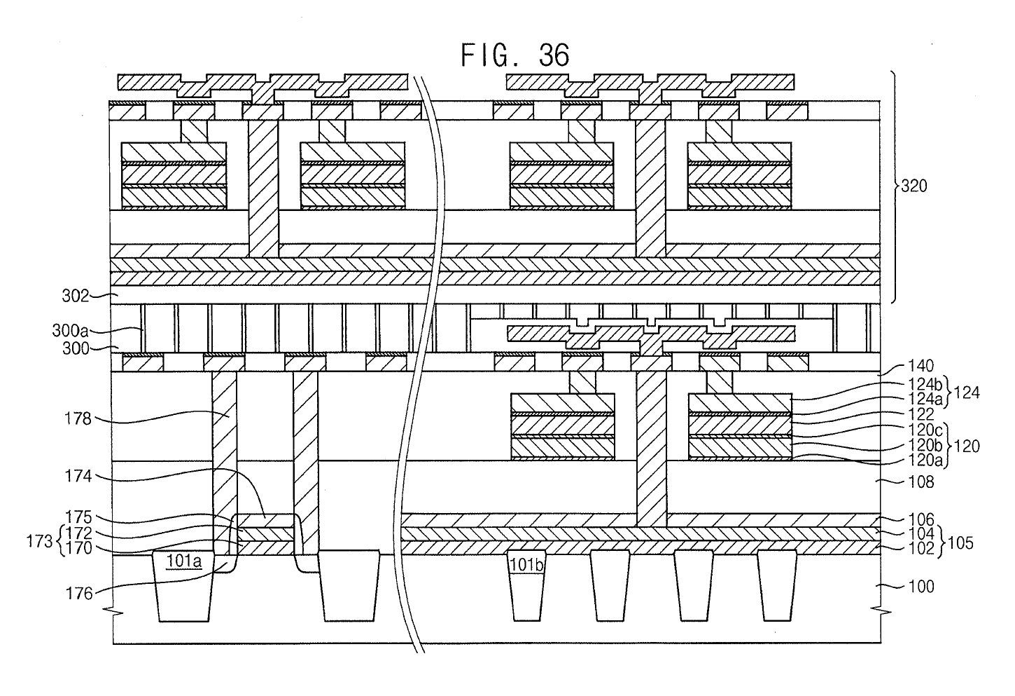

FIG. 36 illustrates a cross-sectional view of an exemplary embodiment of a stacked DRAM device. The stacked DRAM device of FIG. 36 may be substantially similar to the DRAM device of FIG. 32, and may include a stacked structure having a plurality of memory cell arrays vertically stacked.

Referring to FIG. 36, the DRAM device may include a fourth insulating interlayer 300 formed on the DRAM device of FIG. 32. A space may be provided between fourth insulating interlayer 300 and the first conductive plates 166. The fourth insulating interlayer 300 may have a plurality of minute holes 300a extending therethrough. A fifth insulating interlayer 302 may be formed on the fourth insulating interlayer 300. A DRAM device 320 including the memory cells, e.g., as shown in FIG. 1, may be formed on the fifth insulating interlayer 302.

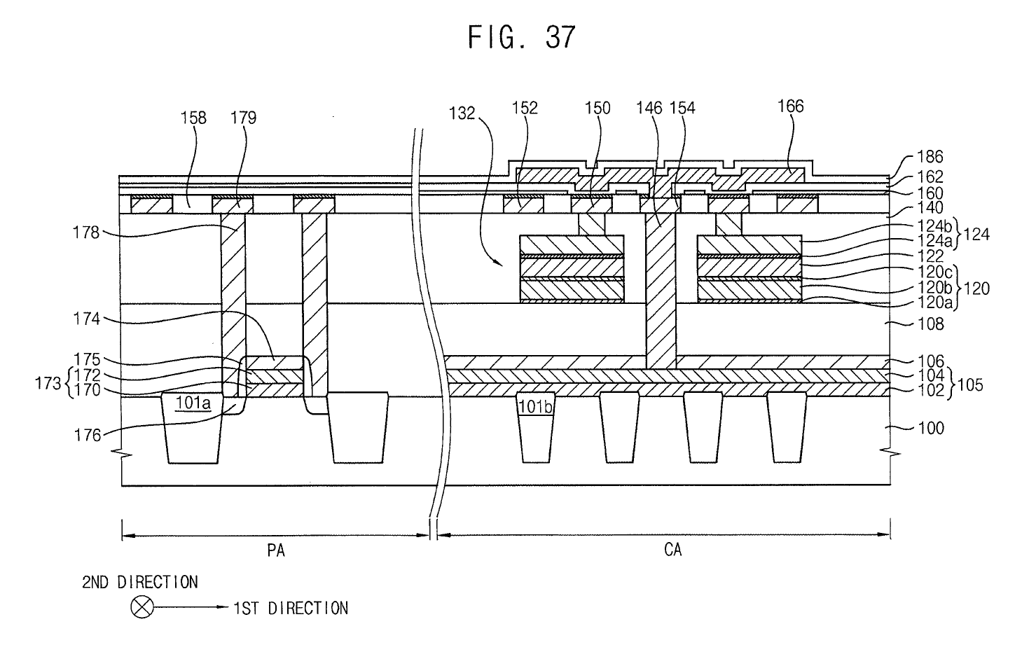

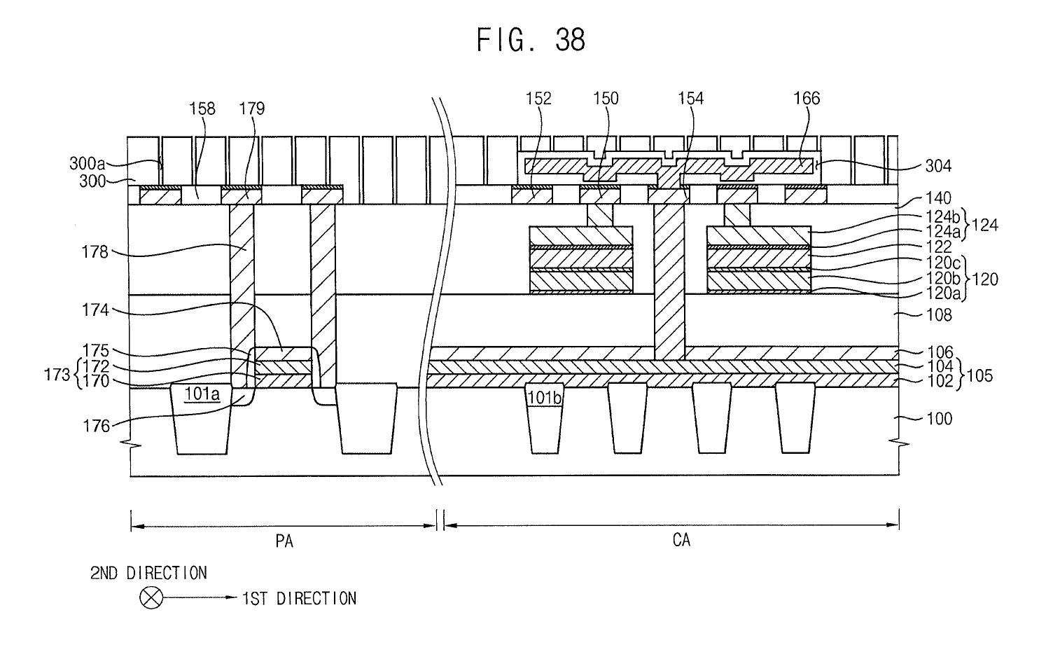

FIGS. 37 and 38 illustrate cross-sectional views of an exemplary method of manufacturing the stacked DRAM device. Process steps substantially similar to those illustrated with reference to FIGS. 33 to 35 may be performed to form the resultant structure of FIG. 35.

Referring to FIG. 37, first and second sacrificial layers 160 and 162 may be sequentially formed on the third insulating interlayer 158 to cover the first and second conductive pads 150 and 154, the word lines 152, and the wirings 179. The plurality of conductive plates 166 contacting the second conductive pads 154 may be formed on the second sacrificial layer 162. Process steps for forming the first and second sacrificial layers 160 and 162 and the first conductive plates 166 may be substantially the same as those illustrated with reference to, e.g., FIGS. 13 to 14.

A third insulating interlayer 186 may be formed on the first conductive plates 166 and the second sacrificial layer 162. The third insulating interlayer 186 may be formed using a material that is substantially similar to that of at least one of the first and second sacrificial layers 160 and 162.

Referring to FIG. 38, the first, second, and third sacrificial layers 160, 162, and 186 may be partially removed so that only portions of the first, second and third sacrificial layers 160, 162 and 186 surrounding the first conductive plates 166 may remain. Thus, portions of the first, second, and third sacrificial layers 160, 162, and 186 in the peripheral region PA may be removed.

A fourth insulating interlayer 300 may be formed on the third sacrificial layer 186, the third insulating interlayer 158, and the wirings 179. The fourth insulating interlayer 300 may have minute holes 300a extending therethrough. The holes 300a may have a proper size so that an etching solution may permeate into the holes 300a. In an exemplary embodiment, the holes 300a may have a diameter of about 10 to about 50 nm. The fourth insulating interlayer 300 may be formed using a self assembly block copolymer. The fourth insulating interlayer 300 may include at least one of polystyrene, polymethylmethacrylate (PMMA), combinations thereof, etc.

In an exemplary embodiment, an etching solution may be provided on the fourth insulating interlayer 300. The etching solution may be provided to the first, second, and third sacrificial layers 160, 162, and 186 via the minute holes 300a in the fourth insulating interlayer 300. Therefore, the first, second and third insulating interlayers 160, 162, and 186 may be removed after the fourth insulating interlayer 300 is formed. Thus, a space 304 may be formed around the first conductive plates 166.

To start the process steps to form the stacked structure of the stacked DRAM device of FIG. 36, a fifth insulating interlayer 302 may be formed on the fourth insulating interlayer 300. For example, the DRAM device 320 formed on the fifth insulating interlayer 302 may have only the memory cells of FIG. 1. Thus, the stacked DRAM device in accordance with an exemplary embodiment may be manufactured.

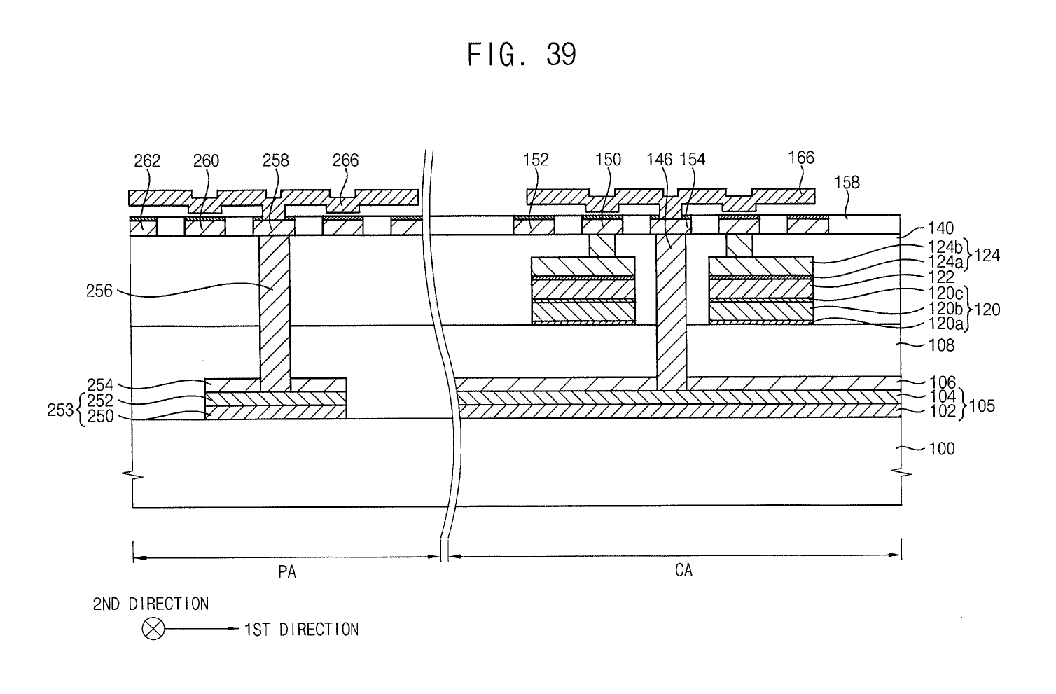

FIG. 39 illustrates a cross-sectional view of an exemplary DRAM device. The DRAM device of FIG. 39 may be substantially similar to the DRAM device of FIG. 32. The DRAM device of FIG. 39 may include electromechanical switches formed in a peripheral region PA.

Referring to FIG. 39, the electromechanical switches, e.g., conductive plates 266 and conductive pads 258, may be formed in the peripheral region PA on the substrate 100. A cell region CA similar to that formed with reference to FIG. 32 may be formed on the substrate 100. As shown in FIG. 39, isolation layers may not be formed on the substrate because MOS transistors may not be formed in the peripheral region PA or the cell region CA.

The peripheral region PA may include a plurality of first wirings 253 formed on the substrate 100. In an exemplary embodiment, an electrical signal may be applied by the first wirings 253 to the electromechanical switches. The first wirings 253 may include a silicon layer 250 and a metal layer 252. The first wirings 253 may be simultaneously formed with the bitlines 105. A fifth hard mask 254 may be formed on the first wirings 253. The fifth hard mask 254 may be simultaneously formed with the first hard marks 106. The first wirings 253 and the hard mask 254 may have a substantially similar structure as that of the bitline structures in the cell region CA.

A third plug 256 may be foamed through the hard mask 254 and the first and second insulating interlayers 108 and 140 on the first wirings 253. A third conductive pad 258 may be formed on the third plug 256. A conductive line 260 and an electrode 262 spaced apart from the third conductive pad 258 may be formed on the second insulating interlayer 140.

A fourth conductive plate 266 contacting the third plug 258 may be formed extending over the conductive line 260 and the electrode 262. A distance between the fourth conductive plate 266 and the conductive line 260 may be smaller than a distance between the fourth conductive plate 266 and the electrode 262. The fourth conductive plate 266 may have a substantially similar shape as that of the first conductive plate 166.

When a voltage is applied to the electrode 262, the fourth conductive plate 266 may move downward and contact the conductive line 260. Thus, the first wirings 253 may be electrically connected to the conductive lines 260 by the movement of the fourth conductive plate 266.

As shown in FIG. 39, the DRAM device may have the electromechanical switches in the peripheral region PA. The DRAM device may have a stacked structure like the stacked DRAM device of FIG. 36.

Experiments were performed with respect to the pull-in voltages of DRAM devices according to an exemplary embodiment of a switching device illustrated in FIG. 3 and a comparative example.

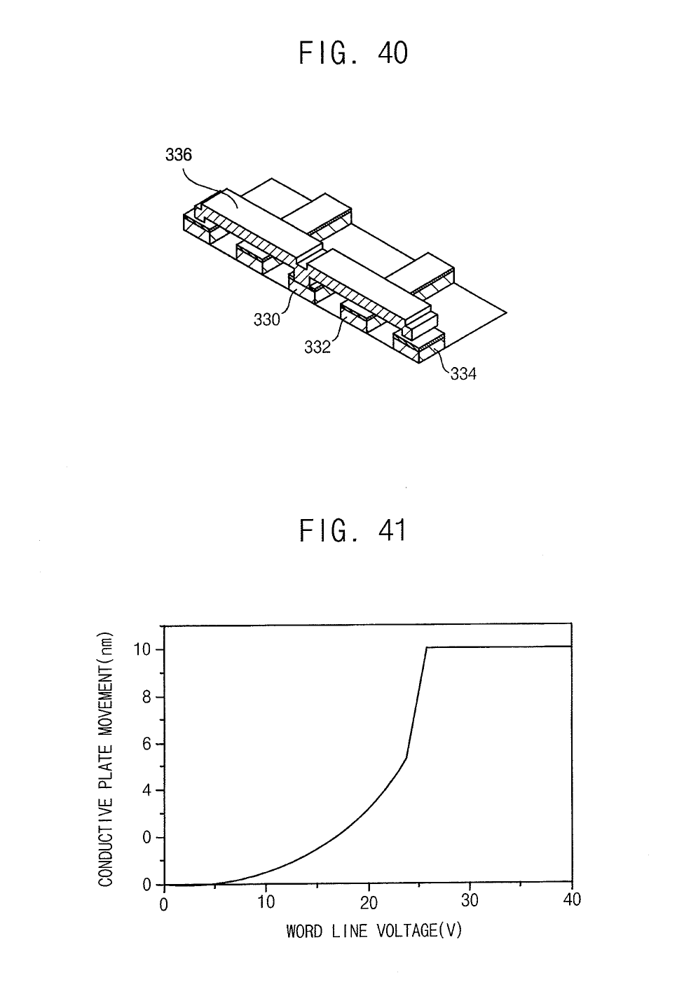

In a first example, i.e., a first switching device substantially the same as that of FIG. 3 was manufactured by a circuit simulation program. In a second example, i.e., in the comparative example, a second switching device of FIG. 40 was manufactured by a circuit simulation program. FIG. 40 illustrates a perspective view of the second switching device. The second switching device has a fifth conductive plate 336 contacting a fifth conductive pad 330, and a blade shape extending over a word line 332 and a fourth conductive pad 334. The fifth conductive pad 330, the word line 332, and the fourth conductive pad 334 are subsequently arranged in the second switching device.

Various voltages were applied to the word lines 152 and 332 of the first and second switching devices, respectively, and movements of the conductive plates 166 and 336 were measured.

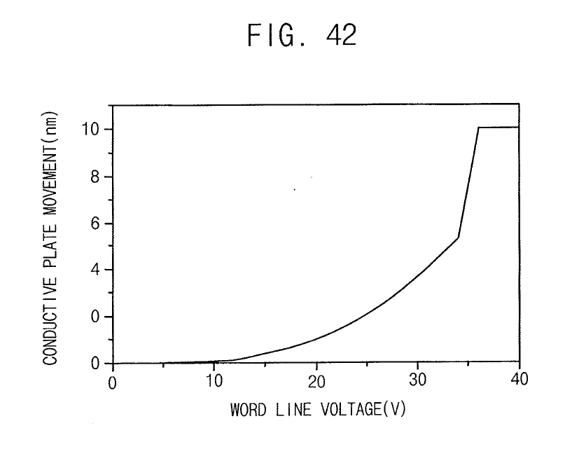

FIG. 41 illustrates a graph showing the movement of the first conductive plate 166 versus the applied voltage to the word line 152. FIG. 42 illustrates a graph showing the movement of the fifth conductive plate 336 versus the applied voltage to the word line 332.

Referring to FIG. 41, the pull-in voltage of the exemplary embodiment was measured to be about 24V, and the pull-in voltage of the comparative example was measured to be about 36V. The DRAM device including the first switching device may have a lower pull-in voltage than the DRAM device including the second switching device by about 33%. Therefore, the DRAM device including the first switching device may be operated by a lower operation voltage.

According to example embodiments, the DRAM device may have low operation voltage and high data retention. Additionally, the DRAM device may have a stacked structure, thereby having high integration degree. Furthermore, the DRAM device may be formed even on a substrate including an insulating material.

Various embodiments are described above with reference to the accompanying drawings, in which some example embodiments are shown. The embodiments may, however, be embodied in many different foams and should not be construed as limited to the example embodiments set forth herein. Rather, these example embodiments are provided so that this description will be thorough and complete, and will fully convey the scope of the embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the embodiments.

Unless otherwise defined, all terms (including technical and scientific terms) used herein have the same meaning as commonly understood by one of ordinary skill in the art to. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The foregoing is illustrative of example embodiments and is not to be construed as limiting thereof Although a few example embodiments have been described, those skilled in the art will readily appreciate that many modifications are possible in the example embodiments without materially departing from the novel teachings and advantages of the embodiments. Accordingly, all such modifications are intended to be included within the scope of the embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A dynamic random access memory (DRAM) device, comprising:
a plug on a substrate;
a conductive plate electrically connected to the plug and overlapping the substrate;
at least one capacitor on the substrate and spaced apart from the plug;
at least one word line under the conductive plate and spaced apart from the conductive plate; and
at least one first conductive pad under the conductive plate, the at least one first conductive pad being spaced apart from the conductive plate in a first state and being electrically connected to the conductive plate in a second state, the at least one first conductive pad being disposed between the plug and an adjacent word line of the at least one word line, and the at least one first conductive pad being electrically connected to a respective capacitor of the at least one capacitor.

2. The device as claimed in claim 1, further comprising a bitline electrically connected to the plug.

3. The device as claimed in claim 2, wherein the bitline extends in a first direction of the substrate and the at least one word line extends in a second direction of the substrate perpendicular to the first direction.

4. The device as claimed in claim 1, wherein:
the conductive plate includes an anchor and a blade, the anchor is electrically connected to the plug, and the blade overlaps a first conductive pad, a second conductive pad, a first word line, and a second word line, and
the first word line, the first conductive pad, the plug, the second conductive pad, and the second word line are sequentially arranged on the substrate in a first direction of the substrate.

5. The device as claimed in claim 1, wherein in the first state a first distance between the conductive plate and the at least one conductive pad is smaller than a second distance between the conductive plate and the at least one word line.

6. The device as claimed in claim 1, further comprising a second conductive pad on the plug, the second conductive pad being disposed on a same plane as the at least one word line is disposed.

7. The device as claimed in claim 1, wherein the at least one capacitor has a stacked structure including a first electrode, a dielectric layer pattern, and a second electrode.

8. The device as claimed in claim 7, wherein:
the first electrode and the at least one word line extend in a second direction, and
the second electrode has an island shape, contacts the conductive pad, and is electrically connected to the conductive plate in the second state.

9. The device as claimed in claim 1, wherein:
the at least one capacitor has a cylindrical shape including a cylindrical first electrode, a cylindrical dielectric layer pattern, and a second electrode, and
the second electrode fills a space formed by the cylindrical dielectric layer pattern.

10. The device as claimed in claim 1, wherein:
the plug, the conductive plate, the at least one capacitor, the at least one word line, and the at least one first conductive pad define a first memory cell of the DRAM device,
the DRAM device includes an insulation layer on the first memory cell, the insulation layer having a space around the conductive plate; and
the DRAM device further includes at least one stacked memory cell on the insulation layer.

11. The device as claimed in claim 1, wherein:
the substrate has a cell region and a peripheral region,
the plug, the conductive plate, the at least one capacitor, the at least one word line, and the first conductive pad define a memory cell in the cell region, and
the peripheral region includes a metal-oxide-semiconductor (MOS) transistor and wirings, the MOS transistor and the wirings being configured to apply an electrical signal to the memory cell.

12-19. (canceled)
